(19) United States
(12) Patent Application Publication
(10) Pub. No.: US 2026/0091402 A1
(43) Pub. Date: Apr. 2, 2026

(54) DEPOSITION MASK AND METHOD OF MANUFACTURING THE SAME

(71) Applicant: Samsung Display Co., LTD., Yongin-si (KR)

(72) Inventors: Jeong Kuk KIM, Yongin-si (KR); Young Jin SONG, Yongin-si (KR); Sug Woo JUNG, Yongin-si (KR); Ji Hyun JUNG, Yongin-si (KR)

(73) Assignee: Samsung Display Co., LTD., Yongin-si (KR)

(21) Appl. No.: 19/188,554

(22) Filed: Apr. 24, 2025

(30) Foreign Application Priority Data
Oct. 2, 2024 (KR) 10-2024-0133635

(51) Int. Cl. B05B 12/20; H10K 59/12; H10K 71/16

(52) U.S. Cl. CPC B05B 12/20; H10K 59/12; H10K 71/166

(57) ABSTRACT

Provided is a deposition mask including a mask substrate including a mask opening; a main coating film including a mask pattern overlapping the mask opening; and a pixel opening defined by the mask pattern, the mask pattern spaced apart from each other by the pixel opening, wherein the mask substrate includes: a first surface facing the main coating film; a second surface facing the first surface; a first side surface connected to the first surface; and a second side surface connecting the first side surface and the second surface, wherein the first side surface forms an undercut with the main coating film, and the mask substrate increases as being closer to the main coating film in a perpendicular direction to the mask substrate.

### CROSS-REFERENCE TO RELATED APPLICATIONS

### This application claims to and benefits of Korean Patent Application No 10-2024-0133635 under 35 USC § 119 filed on October 2 2024 in the Korean Intellectual Property Office the entire contents of which are incorporated herein by reference

### BACKGROUND

### Technical Field

The disclosure relates to a deposition mask and a method of manufacturing the deposition mask.

### Description of the Related Art

With the advance of information-oriented society, more and more demands are placed on display devices for displaying images in various ways. The display device may be a display device such as a liquid crystal display, a field emission display and a light emitting display. The light emitting display may include an organic light emitting display device including an organic light emitting diode as a light emitting element or an inorganic light emitting display device including an inorganic light emitting diode as a light emitting element.

Recently, there is an increasing need for a display device that provides high-resolution images, for example, images with a resolution of 3000 PPI (Pixels Per Inch) or more. To this end, an organic light emitting diode on silicon (OLEDoS), which is a high-resolution small organic light emitting display device, is used. The OLEDoS is an image display device in which an organic light emitting diode (OLED) is disposed on a semiconductor wafer substrate including complementary metal oxide semiconductor (CMOS).

Meanwhile, in order to manufacture a self-luminous display device such as an organic light emitting display device, a deposition method is mainly used as a technology for depositing an organic material for each pixel, in which a thin film mask is firmly attached to a substrate to deposit the organic material at a required position. When depositing the organic material in a large-area organic light emitting display device, a fine metal mask (FMM), which is a thin-film metal mask, is widely used. However, this metal mask is not suitable for high-resolution patterning.

In this regard, in order to manufacture a high-resolution precise thin film mask, a fine silicon mask (FSM) manufactured using a semiconductor substrate such as a wafer is attracting attention.

### SUMMARY

Aspects of the disclosure provide a deposition mask for manufacturing a high-resolution display device and a method of manufacturing the same.

Aspects of the disclosure also provide a deposition mask that improved efficiency of a deposition process and a method of manufacturing the same.

Aspects of the disclosure also provide a deposition mask solving a coating film peeling defect and a method of manufacturing the same.

However, aspects of the disclosure are not restricted to those set forth herein. The above and other aspects of the disclosure will become more apparent to one of ordinary skill in the art to which the disclosure pertains by referencing the detailed description of the disclosure given below.

In an embodiment, a deposition mask may include a mask substrate including a mask opening; a main coating film including a mask pattern overlapping the mask opening; and a pixel opening defined by the mask pattern, the mask pattern spaced apart from each other by the pixel opening, wherein the mask substrate includes: a first surface facing the main coating film; a second surface facing the first surface; a first side surface connected to the first surface; and a second side surface connecting the first side surface and the second surface, wherein the first side surface forms an undercut with the main coating film, and the mask substrate increases as being closer to the main coating film in a perpendicular direction to the mask substrate..

In an embodiment, the first side surface may be recessed toward the main coating film in an opposite direction in which the mask opening may be disposed.

In an embodiment, the main coating film may include a side surface facing the mask opening, and the side surface of the main coating film is protruding toward the mask opening more than the first side surface of the mask substrate.

In an embodiment, the first surface and the second surface may be connected by the first side surface and the second side surface.

In an embodiment, an inclination angle formed between the second surface and the second side surface may include at least one of an obtuse angle or right-angle.

In an embodiment, the main coating film may be in contact with the first surface and the mask substrate may include silicon, and the mask substrate may have a circular shape in a plan view.

In an embodiment, the mask pattern and the main coating film may be disposed on a same line, and the mask pattern and the main coating film may include a same material, and the mask pattern and the main coating film may include silicon nitride.

In an embodiment, in a portion overlapping the first side surface in a direction parallel to the mask substrate, the mask opening may increase as being closer to the main coating film .

In an embodiment, the pixel opening and the mask opening may be connected to each other.

In an embodiment, a method of manufacturing a deposition mask, the method may include: forming a main coating film on a mask substrate and removing a portion of the main coating film to form a pixel opening; forming an auxiliary coating film on the mask substrate in a portion overlapping the pixel opening; removing a portion of the mask substrate to form a mask opening; and removing the auxiliary coating film to allow the pixel opening and the mask opening to be in connection with each other, wherein, in the forming of the auxiliary coating film, the auxiliary coating film may be formed in plural numbers, and each of the auxiliary coating films is spaced apart from each other.

In an embodiment, the method of manufacturing a deposition mask may further include forming a mask pattern overlapping the masking opening and defining the pixel opening, wherein the auxiliary coating films may be spaced apart from each other with respect to the mask pattern.

In an embodiment, in the forming of the auxiliary coating film, the auxiliary coating film may be in contact with the main coating film and the mask pattern.

In an embodiment, the auxiliary coating film may include silicon oxide.

In an embodiment, in the forming of the auxiliary coating film, the auxiliary coating film may be formed by a thermal oxidation (WTO) process.

In an embodiment, in the removing of the mask substrate and the auxiliary coating film, an etching process removing the mask substrate and the auxiliary coating film may be performed in a rear direction of the mask substrate.

In an embodiment, an electronic device may comprise: a display device formed using a deposition mask; the deposition mask comprising: a mask substrate including a mask opening a main coating film including a mask pattern overlapping the mask opening; and a pixel opening defined by the mask pattern, the mask pattern spaced apart from each other by the pixel opening, wherein the mask substrate includes: a first surface facing the main coating film; a second surface facing the first surface; a first side surface connected to the first surface; and a second side surface connecting the first side surface and the second surface, and the first side surface forms an undercut with the main coating film, and the mask substrate increases as being closer to the main coating film in a perpendicular direction to the mask substrate.

In accordance with the deposition mask and the method for manufacturing the same according to an embodiment of the disclosure, it is possible to improve efficiency of a deposition process.

In accordance with the deposition mask and the method for manufacturing the same according to an embodiment of the disclosure, it is possible to solve a coating film peeling defect.

However, effects according to the embodiments of the disclosure are not limited to those exemplified above and various other effects are incorporated herein.

### BRIEF DESCRIPTION OF THE DRAWINGS

0030 The above and other aspects and features of the disclosure will become more apparent by describing in detail embodiments thereof with reference to the attached drawings in which

FIG. 1 is an exploded schematic perspective view showing a display device according to an embodiment;

FIG. 2 is a schematic block diagram illustrating a display device according to an embodiment;

FIG. 3 is a schematic diagram of an equivalent circuit of of a first sub-pixel according to an embodiment;

FIG. 4 is a schematic plan view illustrating an example of a display panel according to an embodiment;

FIGS. 5 and 6 are schematic plan views showing an arrangement of multiple pixels in a display area of FIG. 4;

FIG. 7 is a schematic cross-sectional view illustrating an example of a display panel taken along line X1-X1’ of FIG. 5;

FIG. 8 is an exploded schematic perspective view illustrating a head mounted display according to an embodiment;

FIG. 9 is a schematic perspective view showing an augmented reality content providing device according to an embodiment;

FIG. 10 is a rear exploded schematic perspective view of the augmented reality content providing device of FIG. 9;

FIG. 11 is a front exploded schematic perspective view of the augmented reality content providing device of FIG. 9;

FIG. 12 is a schematic plan view showing a mother semiconductor substrate including a display cell according to an embodiment;

FIG. 13 is a schematic plan view showing a deposition mask including a mask cell according to an embodiment;

FIG. 14 is a schematic diagram for explaining a deposition device that manufactures a display panel by using a deposition mask according to an embodiment;

FIG. 15 is a schematic cross-sectional view taken along line X2-X2’ of FIG. 13;

FIG. 16 is an enlarged schematic cross-sectional view of area M in FIG. 15;

FIG. 17 is a schematic flowchart showing a method of manufacturing a deposition mask according to an embodiment;

FIGS. 18 to 20 are schematic cross-sectional views showing step (S100) of FIG. 17;

FIG. 21 is a schematic cross-sectional view showing step (S200) of FIG. 17;

FIGS. 22 and 23 are schematic cross-sectional views showing step (S300) of FIG. 17;

FIGS. 24 and 25 are schematic cross-sectional views showing step (S400) of FIG. 17;

FIG. 26 is a schematic cross-sectional view of another embodiment taken along line X2-X2’ of FIG. 13;

FIG. 27 is a schematic flowchart showing a method of manufacturing a deposition mask illustrated in FIG. 26;

FIGS. 28 and 29 are schematic cross-sectional views of step (S500) of FIG. 27;

FIGS. 30 and 31 are schematic cross-sectional views of step (S600) of FIG. 27;

FIGS. 32 and 33 are schematic cross-sectional views of step (S700) of FIG. 27;

FIGS. 34 and 35 are schematic cross-sectional views of step (S800) of FIG. 27;

FIG. 36 is a schematic block diagram of an electronic device according to an embodiment; and

FIG. 37 is a schematic diagram of an electronic device according to various embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. The DR1-axis, the DR2-axis, and the DR3-axis are not limited to three axes of a rectangular coordinate system, such as the X, Y, and Z – axes, and may be interpreted in a broader sense. For example, the DR1-axis, the DR2-axis, and the DR3-axis may be perpendicular to one another, or may represent different directions that are not perpendicular to one another. The X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. The blocks, units, and/or modules of some embodiments may be physically combined into more complex blocks, units, and/or modules without departing from the scope of the invention.

Hereinafter, embodiments of the disclosure will be described with reference to the accompanying drawings.

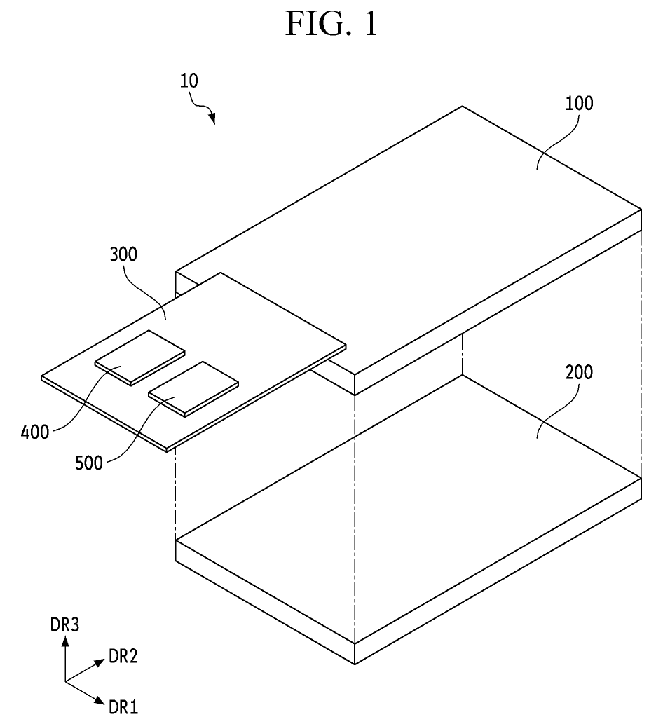

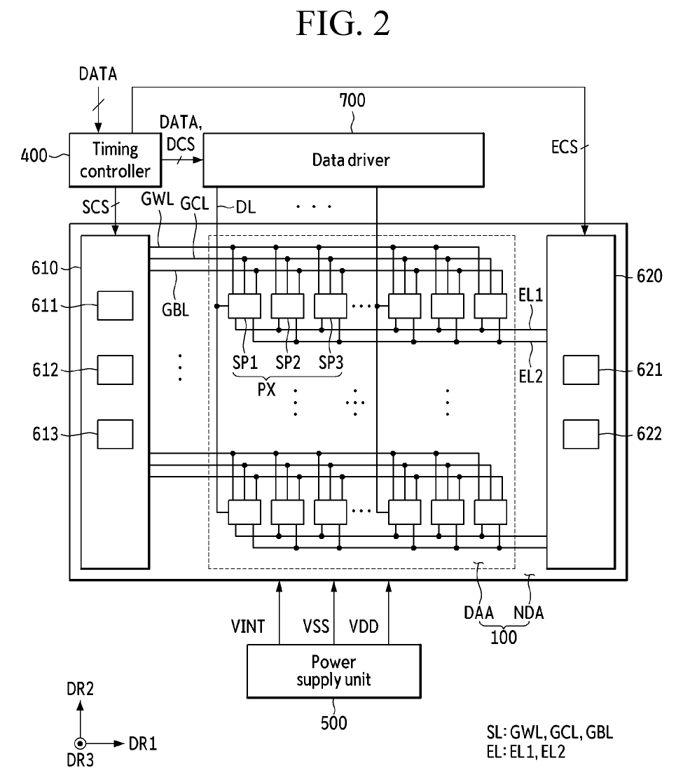

FIG. 1 is an exploded schematic perspective view showing a display device according to an embodiment. FIG. 2 is a schematic block diagram illustrating a display device according to an embodiment.

Referring to FIGS. 1 and 2, a display device 10 according to an embodiment may be a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. In another embodiment, the display device 10 according to an embodiment may be applied to a smart watch, a watch phone, a head mounted display (HMD) for implementing virtual reality and augmented reality, and the like.

The display device 10 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the embodiment of the disclosure is not limited thereto.

In the illustrated figure, the first direction DR1 and the second direction DR2 may cross each other as horizontal directions. For example, the first direction DR1 and the second direction DR2 may be orthogonal to each other. A third direction DR3 may cross the first direction DR1 and the second direction DR2, and they may be, for example, perpendicular directions orthogonal to each other. Unless otherwise defined, in the disclosure, directions indicated by arrows of the first to third directions DR1, DR2, and DR3 may be referred to as a side, and the opposite directions thereto may be referred to as another side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a display area DAA displaying an image and a non-display area NDA not displaying an image as shown in FIG. 2.

The display area DAA may include multiple pixels PX, multiple scan lines SL, multiple emission control lines EL, and multiple data lines DL.

Multiple pixels PX may be arranged in a matrix form in the first direction DR1 and the second direction DR2. Multiple scan lines SL and multiple emission control lines EL may extend in the first direction DR1, while being disposed in the second direction DR2. Multiple data lines DL may extend in the second direction DR2, while being disposed in the first direction DR1.

Multiple scan lines SL may include multiple write scan lines GWL, multiple control scan lines GCL, and multiple bias scan lines GBL. Multiple emission control lines EL may include multiple first emission control lines EL1 and multiple second emission control lines EL2.

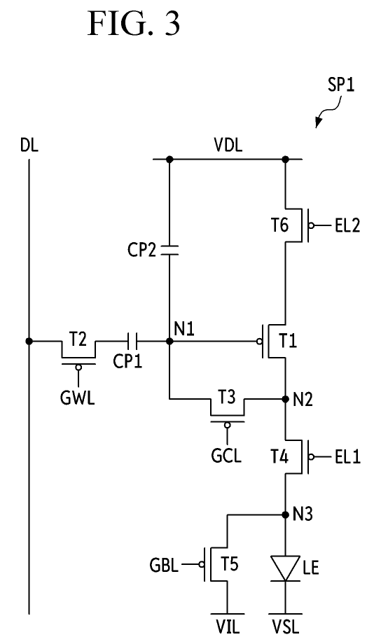

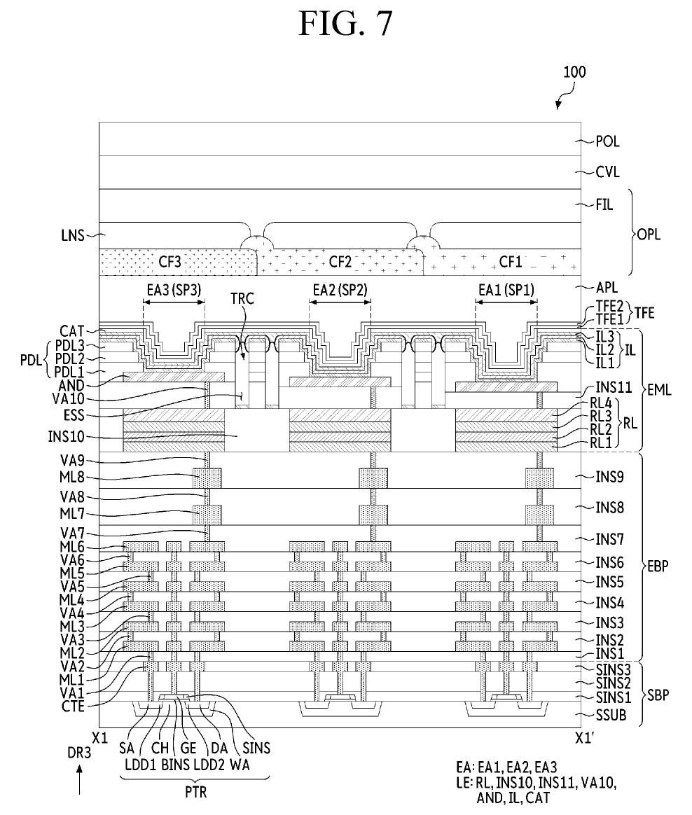

Multiple pixels PX may include multiple sub-pixels SP1, SP2, and SP3. Multiple sub-pixels SP1, SP2, and SP3 may include multiple pixel transistors as shown in FIG. 3 to be described later, and multiple pixel transistors may be formed by a semiconductor process and disposed on a semiconductor substrate SSUB (See FIG. 7). For example, multiple pixel transistors of a data driver 700 may be formed of complementary metal oxide semiconductor (CMOS).

Each of the first to third sub-pixels SP1, SP2, and SP3 may be electrically connected to a write scan line GWL among multiple write scan lines GWL, a control scan line GCL among multiple control scan lines GCL, a bias scan line GBL among multiple bias scan lines GBL, a first emission control line EL1 among multiple first emission control lines EL1, a second emission control line EL2 among multiple second emission control lines EL2, and a data line DL among multiple data lines DL. Each of the first to third sub-pixels SP1, SP2, and SP3 may receive a data voltage of the data line DL in response to a write scan signal of the write scan line GWL, and emit light from the light emitting element according to the data voltage.

The non-display area NDA may include a scan driver 610, an emission driver 620, and the data driver 700.

The scan driver 610 may include multiple scan transistors, and the emission driver 620 includes multiple light emitting transistors. Multiple scan transistors and multiple light emitting transistors may be formed through a semiconductor process, and disposed on the semiconductor substrate SSUB (see FIG. 7). For example, multiple scan transistors and multiple light emitting transistors may be formed of CMOS. Although it is illustrated in FIG. 2 that the scan driver 610 is disposed on the left side of the display area DAA and the emission driver 620 is disposed on the right side of the display area DAA, the disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 may include a first emission control driver 621 and a second emission control driver 622. Each of the first emission control driver 621 and the second emission control driver 622 may receive the emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include multiple data transistors, and multiple data transistors may be formed through a semiconductor process, and disposed on the semiconductor substrate SSUB (see FIG. 7). For example, multiple data transistors may be formed of CMOS.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. For example, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in the third direction DR3, which is the thickness direction of the display panel 100. The heat dissipation layer 200 may be disposed on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), or aluminum (Al).

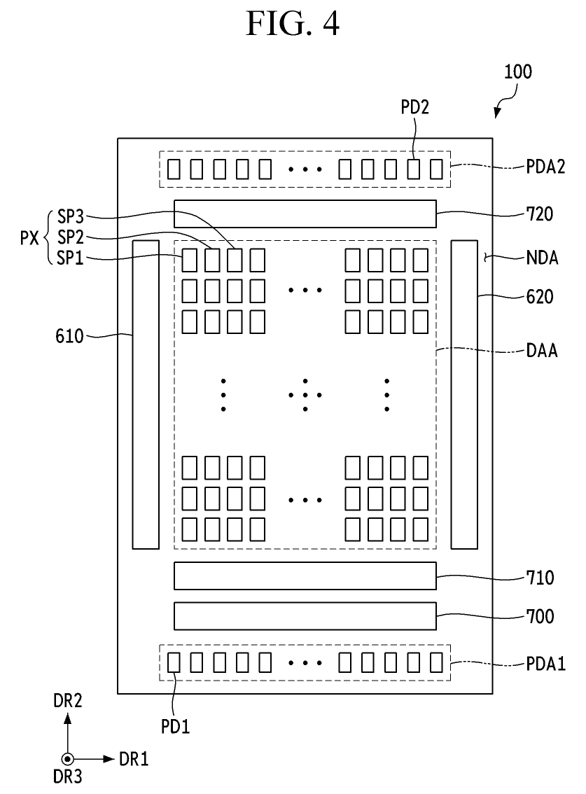

The circuit board 300 may be electrically connected to multiple first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. For example, an end of the circuit board 300 may be disposed on the rear surface of the display panel 100 and/or the rear surface of the heat dissipation layer 200. An end of the circuit board 300 may be an opposite end of the other end of the circuit board 300 electrically connected to multiple first pads PD1 (see FIG. 4) of the first pad portion PDA1 (see FIG. 4) of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate multiple panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. For example, the scan timing control signal SCS, the emission timing control signal ECS, digital video data DATA, and the data timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. For example, the timing control circuit 400 may include multiple timing transistors, and each power supply circuit 500 may include multiple power transistors. Multiple timing transistors and multiple power transistors may be formed through a semiconductor process, and disposed on the semiconductor substrate SSUB (see FIG. 7). For example, multiple timing transistors and multiple power transistors may be formed of CMOS. Each of the timing control circuit 400 and the power supply circuit 500 may be disposed between the data driver 700 and the first pad portion PDA1 (see FIG. 4).

FIG. 3 is a schematic diagram of an equivalent circuit of of a first sub-pixel according to an embodiment.

Referring to FIG. 3 in addition to FIGS. 1 and 2, the first sub-pixel SP1 may be connected to the write scan line GWL, the control scan line GCL, the bias scan line GBL, the first emission control line EL1, the second emission control line EL2, and the data line DL. The first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. For example, the first driving voltage VSS may be lower than the third driving voltage VINT. The second driving voltage VDD may be higher than the third driving voltage VINT.

The first sub-pixel SP1 may include multiple transistors T1 to T6, a light emitting element LE, a first capacitor CP1, and a second capacitor CP2.

The light emitting element LE may emit light in response to a driving current (source-drain current) flowing through the channel of a first transistor T1. A light emission amount of the light emitting element LE may be proportional to the driving current. The light emitting element LE may be disposed between a fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the embodiment of the disclosure is not limited thereto. For example, the light emitting element LE may be an inorganic light emitting element including a first electrode, a second electrode, and an inorganic semiconductor disposed between the first electrode and the second electrode, and the light emitting element LE may be, e.g., a micro light emitting diode.

The first transistor T1 may be a driving transistor that controls a driving current flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 may be turned on by the write control signal of the control scan line GCL to connect the first node N1 to the second node N2. For this reason, since the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 may be disposed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the one electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the embodiment of the disclosure is not limited thereto. Each of the first to sixth transistors T1 to T6 may be an N-type MOSFET. In another embodiment, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, the equivalent circuit diagram of the first sub-pixel SP1 is not limited to that shown in FIG. 3. For example, the number of the transistors and the number of the capacitors of the first sub-pixel SP1 may be changed in various ways.

The equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is omitted in the disclosure.

FIG. 4 is a schematic plan view illustrating an example of a display panel according to an embodiment.

Referring to FIG. 4 in addition to FIGS. 1 to 3, the display area DAA of the display panel 100 according to an embodiment may include multiple pixels PX arranged in a matrix form, and the non-display area NDA may include the scan driver 610, the emission driver 620, the data driver 700, a first distribution circuit 710, a second distribution circuit 720, the first pad portion PDA1, and a second pad portion PDA2. The description of overlapping content of the pixel PX, the scan driver 610, and the emission driver 620 is omitted.

The first pad portion PDA1 may include multiple first pads PD1 electrically connected to pads or bumps of the circuit board 300 through a conductive adhesive member. The first pad portion PDA1 may be disposed on the third side of the display area DAA. For example, the first pad portion PDA1 may be disposed on another side of the display area DAA in the second direction DR2. For example, the first pad portion PDA1 may be disposed on the lower side of the display area DAA.

The first pad portion PDA1 may be disposed outside the data driver 700 in the second direction DR2. For example, the first pad portion PDA1 may be disposed closer to the edge of the display panel 100 than the data driver 700.

The second pad portion PDA2 may include multiple second pads PD2 corresponding to inspection pads that test whether the display panel 100 operates normally. Multiple second pads PD2 may be electrically connected to a jig or a probe pin during an inspection process, or may be electrically connected to a circuit board for inspection. The circuit board for inspection may be a printed circuit board made of a rigid material or a flexible printed circuit board made of a flexible material.

The first distribution circuit 710 may distribute data voltages applied through the first pad portion PDA1 to multiple data lines DL. For example, the first distribution circuit 710 may distribute the data voltages applied through one first pad PD1 of the first pad portion PDA1 to the P (P is a positive integer of 2 or more) data lines DL, and as a result, the number of multiple first pads PD1 may be reduced. The first distribution circuit 710 may be disposed on the third side of the display area DAA of the display panel 100. For example, the first distribution circuit 710 may be disposed on another side of the display area DAA in the second direction DR2. For example, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may inspect the operation of each of the pixels PX in the display area DAA. The second distribution circuit 720 may be disposed on the fourth side of the display area DAA of the display panel 100. For example, the second distribution circuit 720 may be disposed on a side of the display area DAA in the second direction DR2. For example, the second distribution circuit 720 may be disposed on the upper side of the display area DAA.

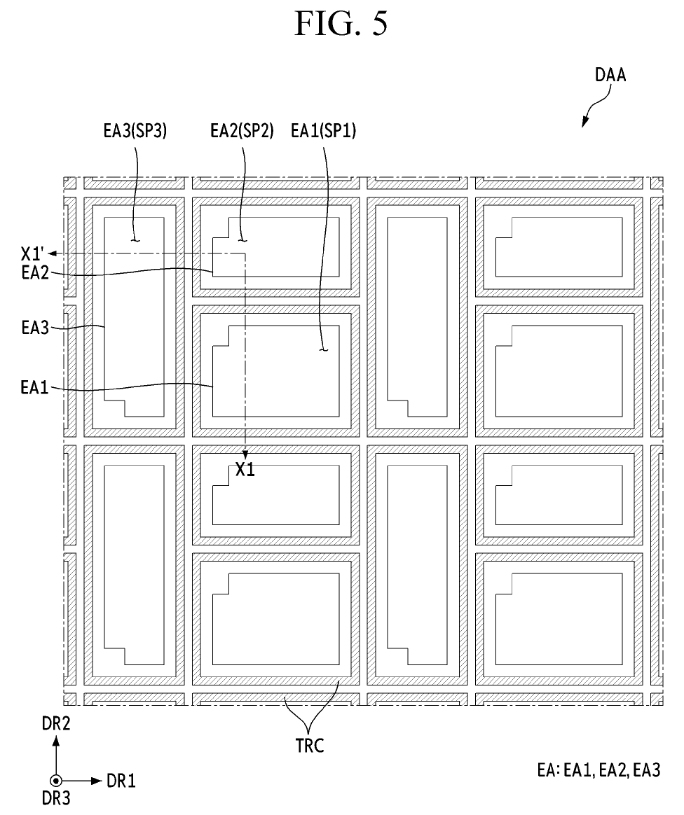

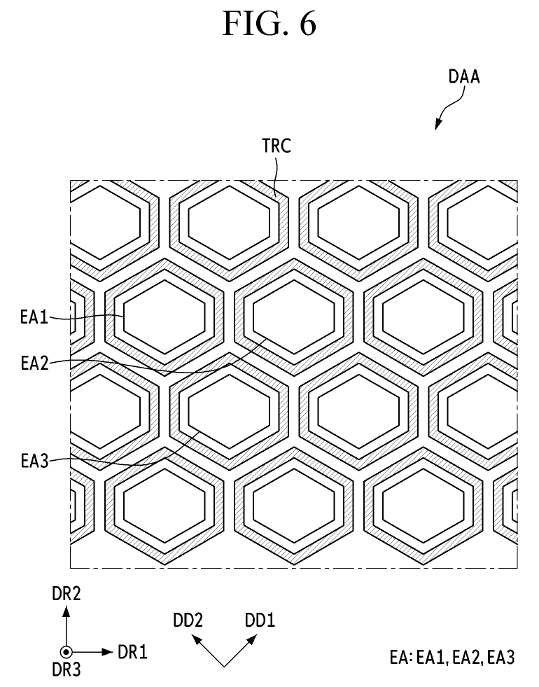

FIGS. 5 and 6 are schematic plan views showing an arrangement of multiple pixels in a display area of FIG. 4.

Referring to FIGS. 5 and 6, each of multiple pixels PX in a portion overlapping the display area DAA may include a first emission area EA1 which is the emission area of the first sub-pixel SP1, a second emission area EA2 which is the emission area of the second sub-pixel SP2, and a third emission area EA3 which is the emission area of the third sub-pixel SP3.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

In some embodiments, the emission area EA may have a stripe structure aligned in the first and second directions DR1 and DR2 and a PenTile® structure having a diamond arrangement as illustrated in FIG. 5, or a hexagonal structure having a hexagonal shape in a plan view as illustrated in FIG. 6. However, the disclosure is not limited thereto, and the emission area EA may have different structure in which a polygonal shape, a circular shape, an elliptical shape, or an atypical shape is arranged in a plan view other than the described structure arrangement.

In some embodiments, in case that the emission area EA has a stripe structure, the first emission area EA1 and the second emission area EA2 may be disposed adjacent to each other in the second direction DR2, and the first emission area EA1 and the third emission area EA3 may be disposed adjacent to each other and the second emission area EA2 and the third emission area EA3 may be disposed adjacent to each other in the first direction DR1. The area of the first emission area EA1, the area of the second emission area EA2, and the area of the third emission area EA3 may be different.

In some embodiments, in case that the emission area EA has a hexagonal structure, the first emission area EA1 and the second emission area EA2 may be adjacent in the first direction, but the second emission area EA2 and the third emission area EA3 may be adjacent in the first diagonal direction DD1, and the first emission area EA1 and the third emission area EA3 may be adjacent in the second diagonal direction DD2. At this time, the first diagonal direction DD1 may intersect each of the first direction DR1 and the second direction DR2 as horizontal directions. For example, the first diagonal direction DD1 may be a direction inclined by 45 degrees with respect to the first direction DR1 and the second direction DR2, but the disclosure is not limited thereto. The second diagonal direction DD2 may intersect each of the first direction DR1 and the second direction DR2 as horizontal directions. For example, the second diagonal direction DD2 may be a direction inclined by 45 degrees with respect to the opposite direction of the first direction DR1 and the second direction DR2, but the disclosure is not limited thereto. The second diagonal direction DD2 may be a direction perpendicular to the first diagonal direction DD1.

It is exemplified in FIGS. 5 and 6 that each of multiple pixels PX includes three emission areas EA1, EA2, and EA3, but the embodiment of the disclosure is not limited thereto. Each of multiple pixels PX may include four or more emission areas.

Each emission area EA including multiple pixels PX may be disposed surrounded by each trench TRC. The trench TRC will be described below.

FIG. 7 is a schematic cross-sectional view illustrating an example of a display panel taken along line X1-X1’ of FIG. 5.

Referring to FIG. 7, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including multiple pixel transistors PTR, a plurality of semiconductor insulating films covering multiple pixel transistors PTR, and a plurality of contact terminals CTE electrically connected to multiple pixel transistors PTR, respectively. Multiple pixel transistors PTR may be the first to sixth transistors T1 to T6 described with reference to FIG. 3.

The semiconductor substrate SSUB may be replaced with a glass substrate or a polymer resin substrate such as polyimide. For example, thin film transistors may be disposed on the glass substrate or the polymer resin substrate. The glass substrate may be a rigid substrate that does not bend, and the polymer resin substrate may be a flexible substrate that can be bent or curved.

The semiconductor substrate SSUB may be a substrate doped with first type impurities. Multiple well regions WA may be disposed on the top surface of the semiconductor substrate SSUB. Multiple well regions WA may be regions doped with a second type impurity. The second type impurity may be different from the aforementioned first type impurity. For example, in case that the first type impurity is a p-type impurity, the second type impurity may be an n-type impurity. In another embodiment, in case that the first type impurity is an n-type impurity, the second type impurity may be a p-type impurity.

Each of multiple well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on another side of the gate electrode GE.

Each of multiple well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase so that punch-through and hot carrier phenomena that might be caused by a short channel are prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but the disclosure is not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but the disclosure is not limited thereto.

Multiple contact terminals CTE may be disposed on the second semiconductor insulating film SINS2. Each of multiple contact terminals CTE may be electrically connected to any one of the gate electrode GE, the source region SA, and the drain region DA of each of the pixel transistors PTR through holes penetrating the first semiconductor insulating film SINS1 and the second semiconductor insulating film SINS2. Multiple contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of multiple contact terminals CTE. The top surface of each of multiple contact terminals CTE may be exposed without being covered by the third semiconductor insulating film SINS3. The third semiconductor insulating film SINS3 may be formed of a silicon oxide (SiOₓ)-based inorganic film, but the disclosure is not limited thereto.

The light emitting element backplane EBP may include multiple conductive layers ML1 to ML8, multiple vias VA1 to VA9, and multiple insulating films INS1 to INS9.

The first to eighth conductive layers ML1 to ML8 may serve to connect multiple contact terminals CTE exposed from the semiconductor backplane SBP to thereby implement the pixel circuit of the first sub-pixel SP1 shown in FIG. 3. For example, the first to sixth transistors T1 to T6 may be disposed (or merely disposed) on the semiconductor backplane SBP, and the connection line of the first to sixth transistors T1 to T6 and the first capacitor CP1 and the second capacitor CP2 may be disposed in the first to eighth conductive layers ML1 to ML8. A connection portion between the drain region corresponding to the drain electrode of the fourth transistor T4, the source region corresponding to the source electrode of the fifth transistor T5, and the first electrode of the light emitting element LE may also be disposed in the first to eighth conductive layers ML1 to ML8.

The first insulating film INS1 may be disposed on the semiconductor backplane SBP. Each of the first vias VA1 may penetrate the first insulating film INS1 and be electrically connected to the contact terminal CTE exposed from the semiconductor backplane SBP. Each of the first conductive layers ML1 may be disposed on the first insulating film INS1 and may be electrically connected to the first via VA1.

The second insulating film INS2 may be disposed on the first insulating film INS1 and the first conductive layers ML1. Each of the second vias VA2 may penetrate the second insulating film INS2 and be electrically connected to the exposed first conductive layer ML1. Each of the second conductive layers ML2 may be disposed on the second insulating film INS2 and may be electrically connected to the second via VA2.

The third insulating film INS3 may be disposed on the second insulating film INS2 and the second conductive layers ML2. Each of the third vias VA3 may penetrate the third insulating film INS3 and be electrically connected to the exposed second conductive layer ML2. Each of the third conductive layers ML3 may be disposed on the third insulating film INS3 and may be electrically connected to the third via VA3.

A fourth insulating film INS4 may be disposed on the third insulating film INS3 and the third conductive layers ML3. Each of the fourth vias VA4 may penetrate the fourth insulating film INS4 and be electrically connected to the exposed third conductive layer ML3. Each of the fourth conductive layers ML4 may be disposed on the fourth insulating film INS4 and may be electrically connected to the fourth via VA4.

A fifth insulating film INS5 may be disposed on the fourth insulating film INS4 and the fourth conductive layers ML4. Each of the fifth vias VA5 may penetrate the fifth insulating film INS5 and be electrically connected to the exposed fourth conductive layer ML4. Each of the fifth conductive layers ML5 may be disposed on the fifth insulating film INS5 and may be electrically connected to the fifth via VA5.

A sixth insulating film INS6 may be disposed on the fifth insulating film INS5 and the fifth conductive layers ML5. Each of the sixth vias VA6 may penetrate the sixth insulating film INS6 and be electrically connected to the exposed fifth conductive layer ML5. Each of the sixth conductive layers ML6 may be disposed on the sixth insulating film INS6 and may be electrically connected to the sixth via VA6.

A seventh insulating film INS7 may be disposed on the sixth insulating film INS6 and the sixth conductive layers ML6. Each of the seventh vias VA7 may penetrate the seventh insulating film INS7 and be electrically connected to the exposed sixth conductive layer ML6. Each of the seventh conductive layers ML7 may be disposed on the seventh insulating film INS7 and may be electrically connected to the seventh via VA7.

An eighth insulating film INS8 may be disposed on the seventh insulating film INS7 and the seventh conductive layers ML7. Each of the eighth vias VA8 may penetrate the eighth insulating film INS8 and be electrically connected to the exposed seventh conductive layer ML7. Each of the eighth conductive layers ML8 may be disposed on the eighth insulating film INS8 and may be electrically connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may be formed of a silicon oxide (SiOₓ)-based inorganic film, but the disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 is about 1360 Å. The thickness of each of the second conductive layer ML2, the third conductive layer ML3, the fourth conductive layer ML4, the fifth conductive layer ML5, and the sixth conductive layer ML6 is about 1440 Å. The thickness of each of the first via VA1, the second via VA2, the third via VA3, the fourth via VA4, the fifth via VA5, and the sixth via VA6 is about 1150 Å. However, the thicknesses of the first to sixth conductive layers ML1, ML2, ML3, ML4, ML5, and ML6 and the first to sixth vias VA1, VA2, VA3, VA4, VA5, and VA6 are not limited thereto.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 is about 9000 Å, and the thickness of each of the seventh via VA7 and the eighth via VA8 is about 6000 Å. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may be formed of a silicon oxide (SiOₓ)-based inorganic film, but the disclosure is not limited thereto.

Each of the ninth vias VA9 may penetrate the ninth insulating film INS9 and be electrically connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include light emitting elements LE, a pixel defining film PDL, and multiple trenches TRC. Each light emitting element LE may include a reflective electrode layer RL, tenth and eleventh insulating films INS10 and INS11, a tenth via VA10, a first electrode AND, a light emitting layer IL, and a second electrode CAT.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7, but is not limited thereto.

Each of the first reflective electrodes RL1 may be disposed on the ninth insulating film INS9, and may be electrically connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

Each of the fourth reflective electrodes RL4 may be disposed on the third reflective electrode RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti).

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 is about 100 Å, and the thickness of the second reflective electrode RL2 is about 850 Å. However, the thicknesses of the first to fourth reflective electrodes RL1, RL2, RL3, and RL4 are not limited thereto.

The tenth insulating film INS10 may be disposed on the ninth insulating film INS9. The tenth insulating film INS10 may be disposed between the reflective electrode layers RL disposed adjacent to each other in a horizontal direction. The tenth insulating film INS10 may be formed of a silicon oxide (SiOₓ)-based inorganic film, but the disclosure is not limited thereto. In some embodiments, although not shown in the drawing, the tenth insulating film INS10 may be disposed not only between the reflective electrode layers RL but also on the reflective electrode layer RL.

The eleventh insulating film INS11 may be disposed on the tenth insulating film INS10 and the reflective electrode layer RL. The eleventh insulating film INS11 may be formed of a silicon oxide (SiOₓ)-based inorganic film, but the disclosure is not limited thereto. The tenth insulating film INS10 and the eleventh insulating film INS11 may be an optical auxiliary layer through which light reflected by the reflective electrode layer RL passes, among light emitted from the light emitting elements LE.

In some embodiments, in at least any one sub-pixel among the first sub-pixel SP1, the second sub-pixel SP2, and the third sub-pixel SP3, in order to adjust the resonance distance of light emitted from the light emitting elements LE, the total thickness of the insulating film disposed between the first electrode AND and the reflective electrode layer RL may be different in the first sub-pixel SP1, the second sub-pixel SP2, and the third sub-pixel SP3.

As shown in the drawing, in case that the tenth insulating film INS10 is not disposed between the first electrode AND and the reflective electrode layer RL but the eleventh insulating film INS11 is disposed therebetween, the thickness of the eleventh insulating film INS11 disposed in each of the first sub-pixel SP1, the second sub-pixel SP2, and the third sub-pixel SP3 may be different. For example, the thickness of the eleventh insulating film INS11 disposed in the first sub-pixel SP1 may be smaller than the thickness of the eleventh insulating film INS11 disposed in the second sub-pixel SP2, and the thickness of the eleventh insulating film INS11 disposed in the second sub-pixel SP2 may be smaller than the thickness of the eleventh insulating film INS11 disposed in the third sub-pixel SP3.

In another embodiment, in the first sub-pixel SP1, neither the tenth insulating film INS10 nor the eleventh insulating film INS11 may be disposed between the first electrode AND and the reflective electrode layer RL, and in the sub-pixel SP2, any one of the tenth insulating film INS10 and the eleventh insulating film INS11 may be disposed between the first electrode AND and the reflective electrode layer RL, and in the third sub-pixel SP3, both the tenth insulating film INS10 and the eleventh insulating film INS11 may be disposed between the first electrode AND and the reflective electrode layer RL.

In another embodiment, a twelfth insulating film may be further disposed between the first electrode AND and the reflective electrode layer RL. For example, in the first sub-pixel SP1, any one of the tenth insulating film INS10, the eleventh insulating film INS11, and the twelfth insulating film may be disposed between the first electrode AND and the reflective electrode layer RL, in the second sub-pixel SP2, any two of the tenth insulating film INS10, the eleventh insulating film INS11, and the twelfth insulating film may be disposed between the first electrode AND and the reflective electrode layer RL, and in the third sub-pixel SP3, all the tenth insulating film INS10, the eleventh insulating film INS11, and the twelfth insulating film may be disposed between the first electrode AND and the reflective electrode layer RL.

In summary, the distance between the first electrode AND and the reflective electrode layer RL may be different in the first sub-pixel SP1, the second sub-pixel SP2, and the third sub-pixel SP3. For example, in order to adjust the distance from the reflective electrode layer RL to the second electrode CAT according to the main wavelength of the light emitted from each of the first sub-pixel SP1, the second sub-pixel SP2, and the third sub-pixel SP3, the presence/absence or thickness of the tenth insulating film INS10 and the eleventh insulating film INS11 may be set in each of the first sub-pixel SP1, the second sub-pixel SP2, and the third sub-pixel SP3.

Although it is illustrated in the drawing that the total thickness of the insulating film disposed between the first electrode AND and the reflective electrode layer RL increases in the order of the first sub-pixel SP1, the second sub-pixel SP2, and the third sub-pixel SP3, the disclosure is not limited thereto. For example, it is illustrated that the distance between the first electrode AND and the reflective electrode layer RL in the third sub-pixel SP3 is greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 is greater than the distance between the first electrode AND and the reflective electrode layer RL in the first sub-pixel SP1, but the disclosure is not limited thereto. The size relationship of the total thickness of the insulating film disposed between the first electrode AND and the reflective electrode layer RL in each of the first sub-pixel SP1, the second sub-pixel SP2, and the third sub-pixel SP3 may be variously changed depending on the resonance distance.

Each of the tenth vias VA10 may be electrically connected to a ninth conductive layer ML9 exposed through the tenth insulating film INS10 and/or the eleventh insulating film INS11. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be less than the thickness of the tenth via VA10 in the third sub-pixel SP3, and the thickness of the tenth via VA10 in the first sub-pixel SP1 may be less than the thickness of the tenth via VA10 in the second sub-pixel SP2, but the disclosure is not limited thereto.

The first electrode AND of each of the light emitting elements LE may be disposed on the eleventh insulating film INS11 and electrically connected to the tenth via VA10. The first electrode AND of each of the light emitting elements LE may be electrically connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may serve to partition each of the first emission areas EA1, the second emission areas EA2, and the third emission areas EA3.

The first emission area EA1 may be defined as an area in which the first electrode AND, the light emitting layer IL, and the second electrode CAT are sequentially stacked in the first sub-pixel SP1 to emit light. The second emission area EA2 may be defined as an area in which the first electrode AND, the light emitting layer IL, and the second electrode CAT are sequentially stacked in the second sub-pixel SP2 to emit light. The third emission area EA3 may be defined as an area in which the first electrode AND, the light emitting layer IL, and the second electrode CAT may be sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but the disclosure is not limited thereto. The first pixel defining film PDL1, the second pixel defining film PDL2, and the third pixel defining film PDL3 may each have a thickness of about 500 Å.

In case that the first pixel defining film PDL1, the second pixel defining film PDL2, and the third pixel defining film PDL3 are formed as one pixel defining film, the height of the one pixel defining film may increase so that a first encapsulation layer TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation layer TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. Each of the width of the first pixel defining film PDL1, the width of the second pixel defining film PDL2, and the width of the third pixel defining film PDL3 refers to the length in the horizontal direction perpendicular to the third direction DR3.

Each of multiple trenches TRC may penetrate the first pixel defining film PDL1, the second pixel defining film PDL2, and the third pixel defining film PDL3. Furthermore, each of multiple trenches TRC may penetrate the eleventh insulating film INS11. The eleventh insulating film INS11 may be partially recessed at each of multiple trenches TRC.

At least one trench TRC may be disposed between the neighboring first to third sub-pixels SP1, SP2, and SP3. Although FIG. 7 illustrates that two trenches TRC are disposed between the neighboring first to third sub-pixels SP1, SP2, and SP3, the disclosure is not limited thereto.

The light emitting layer IL may include multiple stack layers. FIG. 7 illustrates that the light emitting layer IL has a three-tandem structure including a first stack layer IL1, a second stack layer IL2, and a third stack layer IL3, but the disclosure is not limited thereto. For example, the light emitting layer IL may have a two-tandem structure including two stack layers.

In the three-tandem structure, the light emitting layer IL may have a tandem structure including multiple first to third stack layers IL1, IL2, and IL3 that emit different lights. For example, the light emitting layer IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between the neighboring first to third sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of multiple trenches TRC may be a structure for cutting off the first and second stack layers IL1 and IL2, the first charge generation layer, and the second charge generation layer of the display element layer EML between the first to third sub-pixels SP1, SP2, and SP3 disposed adjacent to each other. In addition, in the two-tandem structure, each of the trenches TRC may be a structure for cutting off the charge generation layer disposed between a lower intermediate layer and an upper intermediate layer, and the lower intermediate layer.

The height of each of multiple trenches TRC may be greater than the height of the pixel defining film PDL. This may be for stably cutting off the first and second stack layers IL1 and IL2 of the display element layer EML between adjacent sub-pixels SP1, SP2, and SP3.

The height of each of multiple trenches TRC refers to the length of each of multiple trenches TRC in the third direction DR3. The height of the pixel defining film PDL refers to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining film PDL.

The number of the first to third stack layers IL1, IL2, and IL3 that emit different lights is not limited to that shown in FIG. 7. For example, the light emitting layer IL may include two stack layers. For example, one of the two stack layers may be substantially the same as the first stack layer IL1, and the other may include a second hole transport layer, a second organic light emitting layer, a third organic light emitting layer, and a second electron transport layer. For example, a charge generation layer for supplying electrons to one stack layer and supplying charges to the other stack layer may be disposed between the two stack layers.

In addition, FIG. 7 illustrates that the first to third stack layers IL1, IL2, and IL3 are all disposed in the first emission area EA1, the second emission area EA2, and the third emission area EA3, but the disclosure is not limited thereto. For example, the first stack layer IL1 may be disposed in the first emission area EA1, and may be omitted from the second emission area EA2 and the third emission area EA3. Furthermore, the second stack layer IL2 may be disposed in the second emission area EA2 and may be omitted from the first emission area EA1 and the third emission area EA3. The third stack layer IL3 may be disposed in the third emission area EA3 and may be omitted from the first emission area EA1 and the second emission area EA2. For example, first to third color filters CF1, CF2, and CF3 of the optical layer OPL may be omitted.

The second electrode CAT may be disposed on the third stack layer IL3. The second electrode CAT may be disposed on the third stack layer IL3 in each of multiple trenches TRC.

The second electrode CAT may be formed of a transparent conductive material (TCO) such as ITO or IZO that can transmit light or a semi-transmissive conductive material such as magnesium (Mg), silver (Ag), or an alloy of Mg and Ag. In case that the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include a first encapsulation layer TFE1, and a second encapsulation layer TFE2.

The first encapsulation layer TFE1 may be disposed on the second electrode CAT. The first encapsulation layer TFE1 may be formed as a multilayer in which one or more inorganic films selected from silicon nitride (SiNₓ), silicon oxy nitride (SiON), and silicon oxide (SiOₓ) are alternately stacked. The first encapsulation layer TFE1 may be formed by a chemical vapor deposition (CVD) process.

The second encapsulation layer TFE2 may be disposed on the first encapsulation layer TFE1. The second encapsulation layer TFE2 may be formed of titanium oxide (TiOx) or aluminum oxide (AlOx), but the disclosure is not limited thereto. The second encapsulation layer TFE2 may be formed by an atomic layer deposition (ALD) process. The thickness of the second encapsulation layer TFE2 may be less than the thickness of the first encapsulation layer TFE1.

The display panel 100 may further include an organic film APL. An organic film APL may be a layer for increasing the interfacial adhesion between the encapsulation layer TFE and the optical layer OPL.

The organic film APL may be an organic film such as acrylic resin, epoxy resin, phenolic resin, polyamide resin, or polyimide resin.

The optical layer OPL may include multiple first to third color filters CF1, CF2, and CF3, multiple lenses LNS, and a filling layer FIL.

The first to third color filters CF1, CF2, and CF3 may be disposed on the organic film APL.

The first color filter CF1 may overlap the first emission area EA1 of the first sub-pixel SP1. The first color filter CF1 may transmit light of the first color, i.e., light of a red wavelength band. The red wavelength band may be about 600 nm to about 750 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a blue wavelength band. The blue wavelength band may be about 370 nm to about 460 nm. Thus, the third color filter CF3 may transmit light of the third color among light emitted from the third emission area EA3.

Multiple lenses LNS may be disposed on the first color filter CF1, the second color filter CF2, and the third color filter CF3, respectively. Each of multiple lenses LNS may be a structure for increasing the proportion of light directed to the front of the display device 10. Each of multiple lenses LNS may have a cross-sectional shape that is convex in an upward direction. In some embodiments, multiple lenses LNS may be a micro lens array (MLA).

The filling layer FIL may be disposed on multiple lenses LNS. The filling layer FIL may have a predetermined refractive index such that light travels in the third direction DR3 at an interface between the filling layer FIL and multiple lenses LNS. The filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. In case that the cover layer CVL is a glass substrate, it may be attached onto the filling layer FIL. For example, the filling layer FIL may serve to bond the cover layer CVL. In case that the cover layer CVL is a glass substrate, it may serve as an encapsulation substrate. In case that the cover layer CVL is a polymer resin, it may be applied (or directly applied) onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the disclosure is not limited thereto. However, in case that visibility degradation caused by reflection of external light is sufficiently overcome by the first to third color filters CF1, CF2, and CF3, the polarizing plate POL may be omitted.

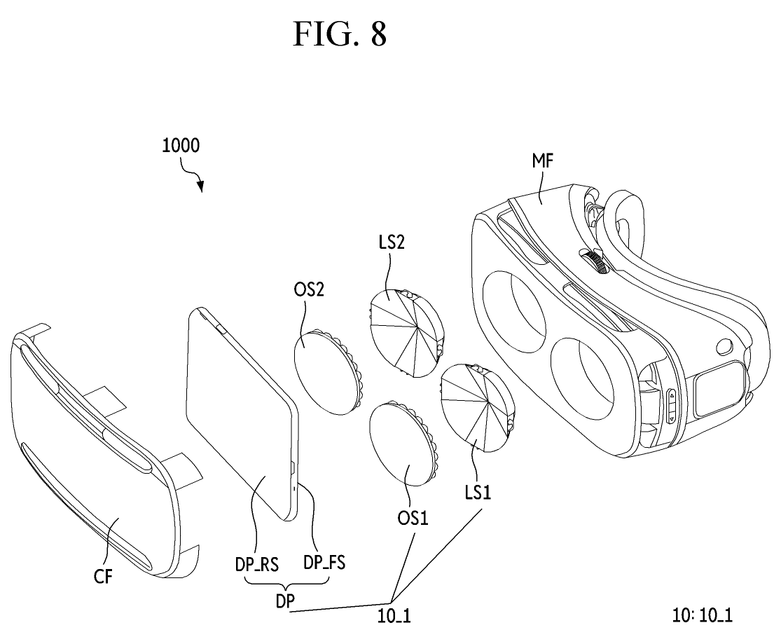

FIG. 8 is an exploded schematic perspective view illustrating a head mounted display according to an embodiment.

Referring to FIG. 8, a head mounted display 1000 may be formed in the form of glasses or a head mount to provide an image to a user using a display device 10_1.

The head mounted display 1000 may include a see-through type that provides augmented reality based on actual external objects and a see-closed type that provides virtual reality to the user on a screen independent from the external objects.

The head mounted display 1000 may include a main frame MF mounted on the user’s body, the display device 10_1 mounted on the main frame MF to display an image, and a cover frame CF that covers the display device 10_1.

The display device 10_1 may be formed integrally with the head mounted display 1000 that may be carried by the user and easily attached to or detached from a face or a head, and may be formed to be assembled to the head mounted display 1000. The display device 10_1 may be substantially the same as the display device 10 described in conjunction with FIG. 1 and the like.

The display device 10_1 may include a display panel DP that displays an image, first and second lens frames OS1 and OS2 that refract an image display light, and first and second multi-channel lenses LS1 and LS2 that form an optical path so that the image display light of the display panel DP is visible to the user.

The main frame MF may be worn on the user’s face and head. The main frame MF may be formed in a shape corresponding to the user’s head and facial structure.

The main frame MF may be integrally formed with display device 10_1, for example, the display panel DP, the first and second lens frames OS1 and OS2, and the first and second multi-channel lenses LS1 and LS2. In another embodiment, the display panel DP, the first and second lens frames OS1 and OS2, and the first and second multi-channel lenses LS1 and LS2 may be assembled and mounted to the main frame MF. To this end, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS disposed on the opposite side of the front surface DP_FS. Image display light may be emitted from the front surface DP_FS of the display panel DP. As will be described later, the first and second lens frames OS1 and OS2 may be disposed on the front surface DP_FS of the display panel DP, and the first and second multi-channel lenses LS1 and LS2 may be disposed on the front surfaces of the first and second lens frames OS1 and OS2. Meanwhile, although not shown, at least one infrared camera may be disposed on at least one of the front surface DP_FS or the rear surface DP_RS of the display panel DP. The display panel DP may be substantially the same as the display panel 100 described in conjunction with FIG. 1 and the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design of the display device 10_1, for example, the usage type of the display device 10_1.

Each of the first and second lens frames OS1 and OS2 may have an area corresponding to the image display surface of the display panel DP, and may be formed in a shape corresponding to that of the image display surface. The first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 refract the image display light emitted from the image display surface of the display panel DP at a preset angle and provide it to the first and second multi-channel lenses LS1 and LS2 disposed on the front surfaces thereof, respectively.

For example, the first and second lens frames OS1 and OS2 may refract the image display light, which is emitted from the image display surface of the display panel DP toward the front side, toward an outer side (or toward an outer peripheral side) compared to the front side and provide it to the first and second multi-channel lenses LS1 and LS2 disposed on the front surfaces thereof, respectively. For example, the first and second lens frames OS1 and OS2 may refract the image display light incident on the rear surfaces thereof toward the outer side (or toward the outer peripheral side) and provide it to the rear surfaces of the first and second multi-channel lenses LS1 and LS2, respectively.

The first and second multi-channel lenses LS1 and LS2 may form a path for light emitted through the first and second lens frames OS1 and OS2 so that the image display light is visible to the user’s eyes on the front side.

The first and second multi-channel lenses LS1 and LS2 may provide multiple channels (or paths) through which the image display light emitted from the display panel DP passes. Multiple channels may provide the image display light emitted from the display panel DP to the user through different paths. The image display light emitted through the first and second lens frames OS1 and OS2 may be incident on the respective channels, and the image magnified through the respective channels may be focused on the user’s eyes.

The first and second multi-channel lenses LS1 and LS2 may be respectively arranged on the front surfaces the first and second lens frames OS1 and OS2 to correspond to the positions of the user’s left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user’s eyes. At least one infrared light source may be further disposed at the main frame MF, or on a side of each of the first and second multi-channel lenses LS1 and LS2 facing the user’s eyes.

The cover frame CF may be disposed on the rear surface DP_RS of the display panel DP to cover the display panel DP and may protect the display panel DP. The cover frame CF may be attached to the main frame MF while covering the display panel DP.

Although not shown, the display device 10_1 may further include a controller for controlling the overall operation of the display device 10_1 including the display panel DP. The controller may control the image display operation of the display panel DP and audio devices. For example, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but is not limited thereto.

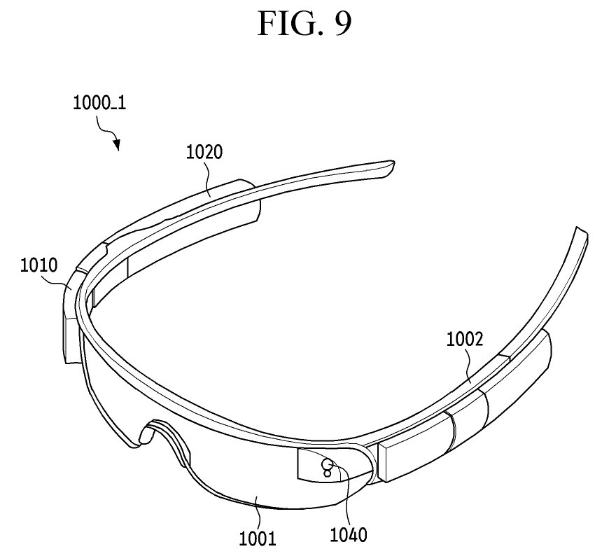

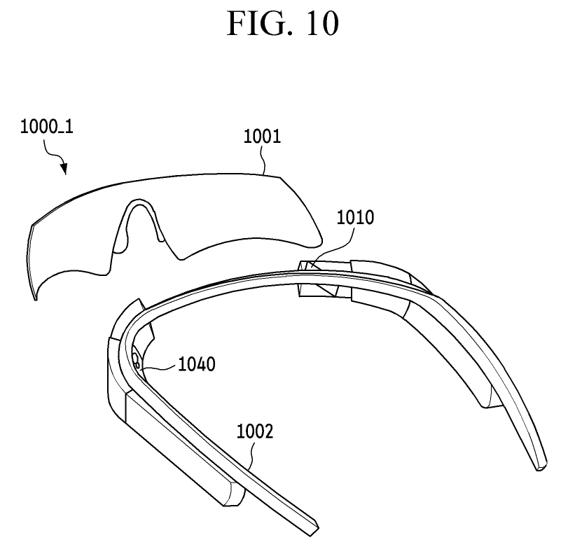

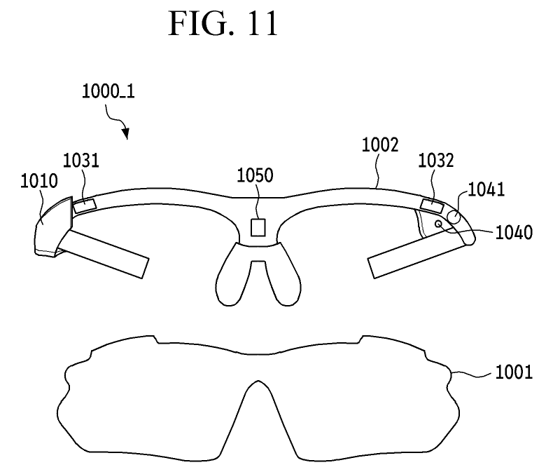

FIG. 9 is a schematic perspective view showing an augmented reality content providing device according to an embodiment. FIG. 10 is a rear exploded schematic perspective view of the augmented reality content providing device of FIG. 9, and FIG. 11 is a front exploded schematic perspective view of the augmented reality content providing device of FIG. 9.

Referring to FIGS. 9 to 11, an augmented reality content providing device 1000_1 may include a support frame 1002 supporting at least one transparent lens 1001, at least one image display module 1010, a surrounding environment detector 1040, and a control module 1020.

The support frame 1002 may be formed in the form of glasses including a spectacle frame supporting the edge of at least one transparent lens 1001 and spectacle frame legs. The shape of the support frame 1002 is not limited to a glasses type, and may be formed in a goggle type including the transparent lens 1001, or a head mount type.

The transparent lens 1001 may include left and right parts formed integrally, or first and second transparent lenses formed separately. The transparent lens 1001, which includes the integrated left and right parts or the separated first and second transparent lenses, may be made of glass or plastic that is transparent or translucent. Accordingly, the user can view the image of reality through the transparent lens 1001 that includes the integrated right and left parts or the separated first and second transparent lenses. Here, the transparent lens 1001, for example, the integrated lens or the first and second transparent lenses, may have a refractive power in consideration of the user’s eyesight.

The transparent lens 1001 may further include at least one reflective member that reflects the augmented reality content image provided from the at least one image display module 1010 toward the transparent lens 1001 or the user’s eyes, and optical members that adjust a focus and a size. One or more reflective member may be built in the transparent lens 1001 to be integrated with the transparent lens 1001, and may be formed as multiple refractive lenses or multiple prisms with a predetermined curvature.

The at least one image display module 1010 may include a micro LED display device (micro-LED), a nano LED display device (nano-LED), an organic light emitting display device (OLED), an inorganic light emitting display device (inorganic EL), a quantum dot light emitting display device (QED), a cathode ray display (CRT), a liquid crystal display (LCD), or the like. The image display module 1010 may substantially include the display device 10 described with reference to FIG. 1 and the like.

The surrounding environment detector 1040 is assembled or integrally formed with the support frame 1002, and detects the distance (or depth) to an object on the front side of the support frame 1002, the illuminance, the moving direction of the support frame 1002, the moving distance, the tilt, or the like. To this end, the surrounding environment detector 1040 includes a depth sensor 1041 such as an infrared sensor or a LiDAR sensor, and an image sensor 1050 such as a camera. The surrounding environment detector 1040 may further include at least one motion sensor among an illumination sensor, a human body detection sensor, a gyro sensor, a tilt sensor, and an acceleration sensor. The surrounding environment detector 1040 may further include first and second biometric sensors 1031 and 1032 for detecting movement information of the user’s eyes or pupils.

The surrounding environment detector 1040 may transmit sensing signals generated by the depth sensor 1041 and at least one motion sensor to the control module 1020 in real time. The image sensor 1050 may transmit image data in units of at least one frame generated in real time to the control module 1020. The first and second biometric sensors 1031 and 1032 of the surrounding environment detector 1040 may transmit the detected pupil detection signals to the control module 1020.

The control module 1020 may be assembled to at least a side of the support frame 1002 together with the at least one image display module 1010 or may be formed integrally with the support frame 1002. The control module 1020 may supply augmented reality content data to the at least one image display module 1010 so that the at least one image display module 1010 displays an augmented reality content, e.g., an augmented reality content image. At the same time, the control module 1020 may receive sensing signals, image data, and pupil detection signals from the surrounding environment detector 1040 in real time.

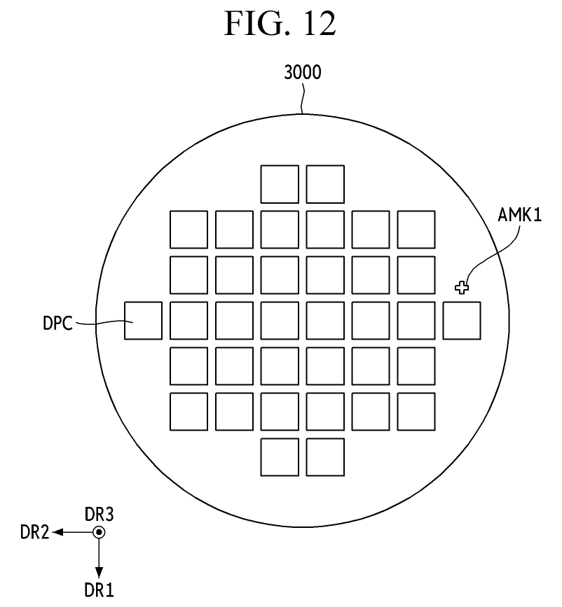

FIG. 12 is a schematic plan view showing a mother semiconductor substrate including a display cell according to an embodiment.

Referring to FIG. 12 in addition to FIGS. 1 to 11, a mother semiconductor substrate 3000 may be composed of a semiconductor wafer. The mother semiconductor substrate 3000 may contain a group IV material or a group III-V compound. In some embodiments, the mother semiconductor substrate 3000 may be formed as a monocrystalline wafer. For example, the mother semiconductor substrate 3000 may be a silicon substrate, a germanium substrate, or a silicon-germanium substrate.

However, the mother semiconductor substrate 3000 is not limited to a single-crystal wafer, and may be any of various types of wafers such as an epi or epitaxial wafer, a polished wafer, an annealed wafer, and an SOI (silicon on insulator) wafer. An epitaxial wafer is a wafer in which a crystalline material is grown on a single-crystal silicon substrate.

The mother semiconductor substrate 3000 may include a first alignment mark AMK1. The first alignment mark AMK1 will be described below.

The mother semiconductor substrate 3000 may include multiple display cells DPC. Multiple display cells DPC may be preprocessing components that form part of the display panel 100 described above. For example, the mother semiconductor substrate 3000 may form the semiconductor substrate SSUB of the display panel 100, and multiple display cells DPC may form the semiconductor backplane SBP, the display element layer EML, and an encapsulation layer TFE.

Multiple display cells DPC may be formed using a semiconductor apparatus or may be formed through a semiconductor process, but the disclosure is not limited thereto. The display panel 100 may be formed by forming multiple display cells DPC, and then cell-cutting in each display cell DPC units.

Although not shown in the drawing, each of the display cells DPC may include multiple pixels PX, and each of the pixels PX may include multiple light emitting elements. The light emitting layer IL included in the light emitting element may be formed through a deposition process. In general, in order to form the light emitting layer IL in the high-resolution display device 10 through a deposition process, a more precise deposition mask may be required. Hereinafter, a deposition mask for forming the high-resolution display device 10 will be described.

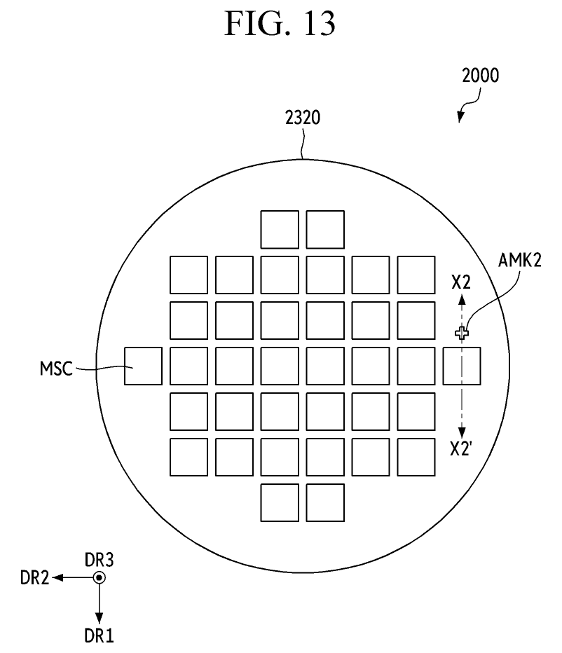

FIG. 13 is a schematic plan view showing a deposition mask including a mask cell according to an embodiment.

Referring to FIG. 13 in addition to FIGS. 1 to 12, a deposition mask 2000 according to an embodiment may be a deposition mask for use in manufacturing an ultra-high resolution display. For example, the deposition mask 2000 may be a deposition mask for use in manufacturing a display included in the head mounted display device or an augmented reality content providing device.

The deposition mask 2000 may be used to perform a pixel deposition process on a silicon wafer. In general, in the case of a display included in an extended reality device, since a screen is positioned (or directly positioned) in front of the user’s eyes, it may have a small screen rather than a large one. Since the display is positioned close to the user’s eyes, ultra-high resolution may be required. For example, the required resolution of the display included in the extended reality device may be about 1000 PPI or more, and, desirably, an ultra-high resolution of about 3000 PPI or more may be required. The deposition mask 2000 according to an embodiment may be a mask for use in manufacturing such an ultra-high resolution display. In another embodiment, the deposition mask 2000 may be a fine silicon mask (FSM).

The deposition mask 2000 may include a mask substrate 2320 and multiple mask cells MSC. The mask substrate 2320 may be disposed to surround each mask cell MSC.

The mask substrate 2320 may be composed of a semiconductor wafer. The mask substrate 2320 may contain a group IV material or a group III-V compound. In some embodiments, the mask substrate 2320 may be composed of a single-crystal wafer. For example, the mask substrate 2320 may be a silicon substrate, a germanium substrate, or a silicon-germanium substrate. However, the mask substrate 2320 is not limited to the single-crystal wafer, and may be any of various types of wafers such as an epi or epitaxial wafer, a polished wafer, an annealed wafer, and an SOI (silicon on insulator) wafer. An epitaxial wafer is a wafer in which a crystalline material is grown on a single-crystal silicon substrate.

The mask substrate 2320 may have the same size or shape as the mother semiconductor substrate 3000 as a substrate of an ultra-high resolution display.

Multiple mask cells MSC may be arranged to correspond to multiple display cells DPC of the mother semiconductor substrate 3000. For example, in a deposition process for manufacturing the display device 10, multiple mask cells MSC may overlap multiple display cells DPC of the mother semiconductor substrate 3000, respectively.

At this time, to align multiple mask cells MSC to overlap multiple display cells DPC, the mother semiconductor substrate 3000 may include a first alignment mark AMK1, and the deposition mask 2000 may include a second alignment mark AMK2. The first alignment mark AMK1 and the second alignment mark AMK2 may each contain metal, but are not limited thereto.

Multiple mask cells MSC may be formed using semiconductor equipment or through a semiconductor process, but are not limited thereto. By forming multiple mask cells MSC on the mask substrate 2320 composed of a semiconductor wafer using semiconductor equipment or through a semiconductor process, the deposition mask 2000 according to the present embodiment may be provided with an ultra-high resolution pattern. An ultra-high resolution display may be manufactured using this ultra-high resolution pattern.

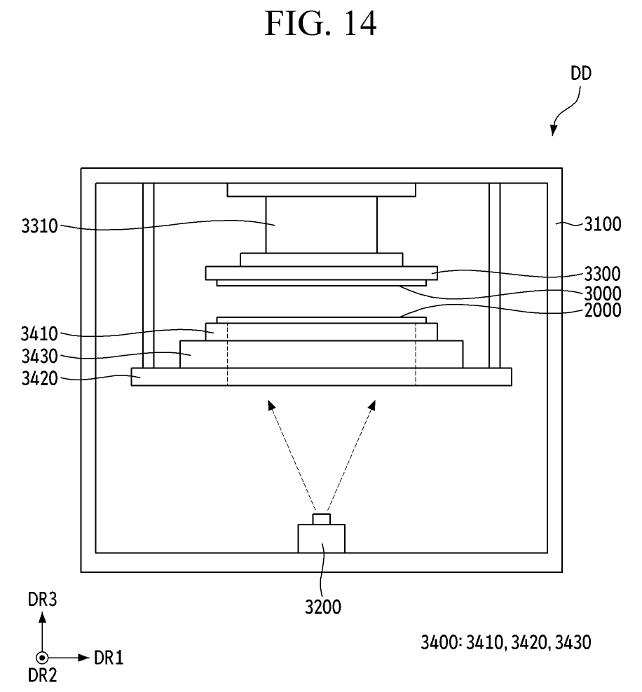

FIG. 14 is a schematic diagram for explaining a deposition device that manufactures a display panel by using a deposition mask according to an embodiment.

Referring to FIG. 14 in addition to FIGS. 1 to 13, a deposition device DD may be used to form light emitting material layers on the mother semiconductor substrate 3000 in a manufacturing process of the display panel 100. In another embodiment, the deposition device DD may be used to form the light emitting layer IL illustrated in FIG. 7.

The deposition device DD may include a process chamber 3100. The process chamber 3100 may have an internal space, and a deposition process for forming a deposition material layer on the mother semiconductor substrate 3000 may be performed in the internal space of the process chamber 3100. Although not illustrated, the process chamber 3100 may be connected to a vacuum pump (not illustrated), and the internal space of the process chamber 3100 may be created into a vacuum atmosphere by the vacuum chamber. An opening (not illustrated) for the entry and exit of the mother semiconductor substrate 3000 and the deposition mask 2000 may be provided on a side wall of the process chamber 3100, and may be opened and closed by a gate valve (not illustrated).

The deposition mask 2000 and the mother semiconductor substrate 3000 may be disposed to face each other. For example, the deposition mask 2000 may be disposed to face a side of the third direction DR3, and the mother semiconductor substrate 3000 may be disposed to face another side of the third direction DR3. The mother semiconductor substrate 3000 may be supported by a substrate chuck 3300. For example, the substrate chuck 3300 may support the mother semiconductor substrate 3000 so that the front side of the mother semiconductor substrate 3000 faces downward, and may position the mother semiconductor substrate 3000 on the deposition mask 2000 to perform a deposition process.

An upper driving unit 3310 moving and rotating the substrate chuck 3300 may be disposed above the substrate chuck 3300 to adjust the position and angle of the mother semiconductor substrate 3000. For example, the upper driving unit 3310 may move the substrate chuck 3300 in the first and second directions DR1 and DR2 to adjust the horizontal position of the mother semiconductor substrate 3000, may move the substrate chuck 3300 in the third direction DR3 to adjust the vertical position of the mother semiconductor substrate 3000, and may rotate the substrate chuck 3300 in the third direction DR3. For example, the first direction DR1, the second direction DR2, and the third direction DR3 may be an X-axis direction, a Y-axis direction, and a Z-axis direction, respectively.

The deposition mask 2000 may be disposed on a mask stage 3400. The mask stage 3400 may include a mask chuck 3410 for supporting the deposition mask 2000, a support plate 3420, and a lower driving unit 3430.

The mask chuck 3410 may have a circular ring shape to support the edge portion of the deposition mask 2000. For example, the mask chuck 3410 may be an electrostatic chuck to hold the edge portion of the deposition mask 2000 using an electrostatic force.

The support plate 3420 may have an opening to allow the deposition mask 2000 to be exposed toward the deposition source 3200, and the lower driving unit 3430 for adjusting the position and angle of the lower deposition mask 2000 may be disposed between the support plate 3420 and the mask chuck 3410. For example, the lower driving unit 3430 may move the mask chuck 3410 in the first and second directions DR1 and DR2 to adjust the horizontal position of the deposition mask 2000, and may rotate the mask chuck 3410 around the Z-axis to adjust the azimuthal angle of the deposition mask 2000.

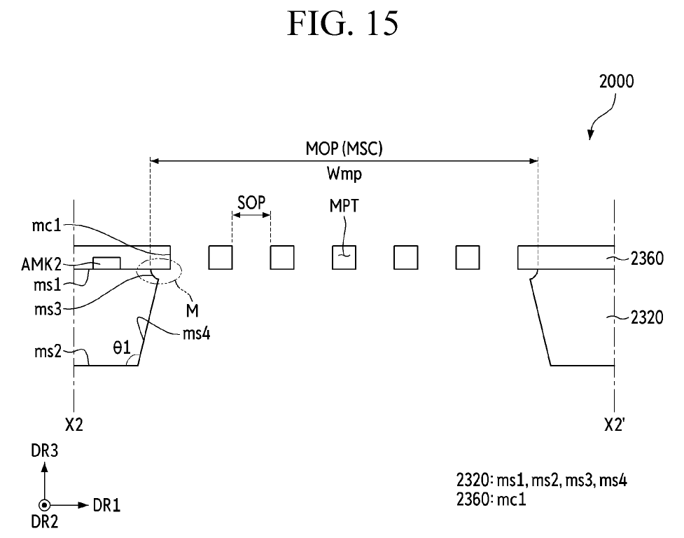

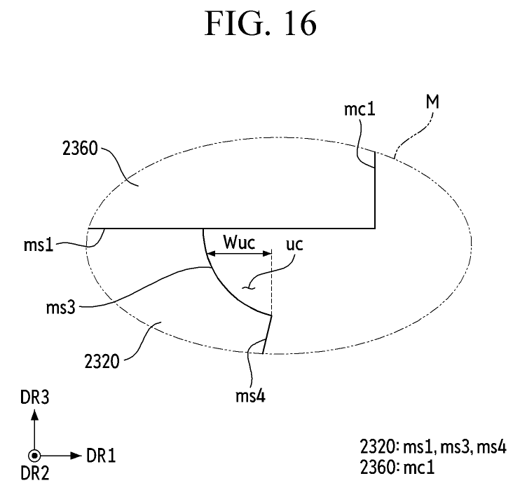

FIG. 15 is a schematic cross-sectional view taken along line X2-X2’ of FIG. 13, and FIG. 16 is an enlarged schematic cross-sectional view of area M in FIG. 15.

Referring to FIGS. 15 and 16 in addition to FIGS. 1 to 14, the deposition mask 2000 according to an embodiment may include a mask substrate 2320, a second alignment mark AMK2, a main coating film 2360, and a mask pattern MPT.

The mask substrate 2320 may define a mask opening MOP and be disposed to surround the mask opening MOP. The mask opening MOP may be plural in number, corresponding to the mask cells MSC. For example, multiple mask openings MOP may be respectively disposed for multiple mask cells MSC. However, the disclosure is not limited thereto, and the mask opening MOP may be formed as one across the plurality of mask cells MSC.

The mask substrate 2320 may include a first surface ms1, a second surface ms2, a first side surface ms3, and a second side surface ms4.

The first surface ms1 of the mask substrate 2320 may be one surface facing toward the main coating film 2360, the second surface ms2 thereof may be one surface facing the first surface ms1, and the first side surface ms3 and the second side surface ms4 thereof may be surfaces facing the mask opening MOP. The first side surface ms3 may be one surface connecting the first surface ms1 and the second side surface ms4, and the second side surface ms4 may be one surface connecting the second surface ms2 and the first side surface ms3.

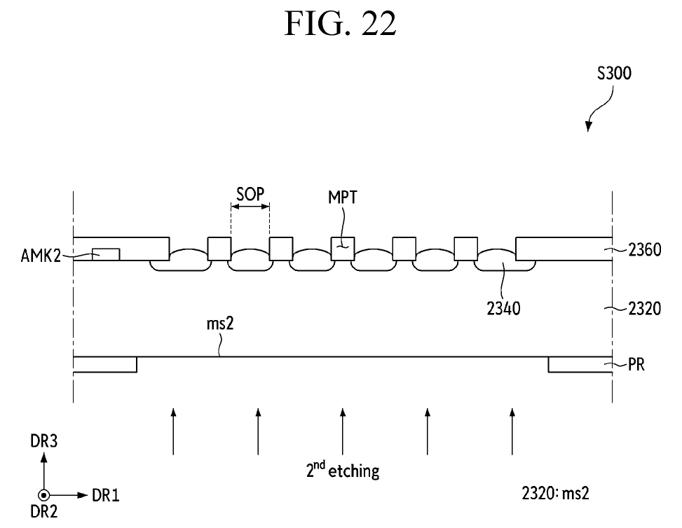

In some embodiments, the first side surface ms3 of the mask substrate 2320 may have a shape recessed toward the main coating film 2360 in the opposite direction to the direction in which the mask opening MOP is disposed. Accordingly, an undercut us may be formed between the main coating film 2360 and the first surface ms3 of the mask substrate 2320. The undercut us described above may be formed as a part of the mask substrate 2320 is oxidized in a manufacturing process of an auxiliary coating film 2340 (see FIG. 22) among the manufacturing process of the deposition mask 2000. The manufacturing process will be described below.

A width Wuc may be increased towards the main coating film 2360. This may have the same meaning as a width Wmp of the mask opening MOP increasing toward the main coating film 2360 in the portion overlapping the first side surface ms3 of the mask substrate 2320 in the first direction DR1.

An inclination angle θ1 formed by the second surface ms2 and the second side surface ms4 of the mask substrate 2320 may vary depending on the type of the process etching the mask substrate 2320 among the process of manufacturing the deposition mask 2000. For example, in case that a dry-etching process is performed as the etching process of the mask substrate 2320, the inclination angle θ1 may be right-angled. On the other hand, in case that a wet-etching process is performed as the etching process of the mask substrate 2320, the inclination angle θ1 may be an obtuse angle. Details will be described below.

The second alignment mark AMK2 may be disposed on the first surface ms1 of the mask substrate 2320. However, the disclosure is not limited thereto, and the second alignment mark AMK2 may be disposed on the main coating film 2360. A description of overlapping contents is omitted.

The main coating film 2360 may be disposed on the second alignment mark AMK2 and the mask substrate 2320. The main coating film 2360 may be disposed to contact the first surface ms1 of the mask substrate 2320. The main coating film 2360 may be disposed to surround the mask opening MOP.

The main coating film 2360 may be an inorganic film including inorganic material, and for example, may contain silicon nitride (SiNₓ) having tensile stress properties.

The main coating film 2360 may have a side surface mc1 protruding toward the mask opening MOP from the second side surface ms4 of the mask substrate 2320, but the disclosure is not limited thereto.

In some embodiments, the main coating film 2360 may be disposed on the second surface ms2 of the mask substrate 2320, but the disclosure is not limited thereto.

The deposition mask 2000 according to an embodiment may include multiple mask patterns MPT in a portion that overlaps the mask opening MOP. Multiple mask patterns MPT may not overlap the mask substrate 2320 in the third direction DR3.

The respective mask patterns MPT may be spaced apart from each other with a pixel opening SOP interposed therebetween, and some mask patterns MPT may be spaced apart from the main coating film 2360 with a pixel opening SOP interposed therebetween.

Multiple mask patterns MPT may be spaced apart from each other in the first direction DR1 or the second direction DR2 in cross section, but may be one pattern connected to each other in a plan view. In another embodiment, the mask pattern MPT may refer to all of multiple patterns positioned on the mask substrate 2320 as one configuration or may refer to each of multiple patterns. For example, multiple mask patterns MPT may be used interchangeably to refer to the entirety of a group of multiple patterns as one configuration or refer to each of multiple patterns.

The mask pattern MPT may include the same material as the main coating film 2360. In the manufacturing process of the deposition mask 2000, the mask pattern MPT and the main coating film 2360 may be formed integrally with each other, and portions of the main coating film 2360 may be then removed by a subsequent etching process, and accordingly, the mask pattern MPT and the main coating film 2360 may be divided into forms of the mask pattern MPT and the main coating film 2360 illustrated in the drawing.

In some embodiments, the mask pattern MPT may have a reverse tapered shape, but is not limited thereto.

The pixel opening SOP according to an embodiment may be in connection with the mask opening MOP. Accordingly, the mask opening MOP and the pixel opening SOP may provide a passage through which a deposition material for forming the pixel PX of the display panel 100 included in the display device 10 may move.

Hereinafter, a method of manufacturing the deposition mask 2000 will be described.

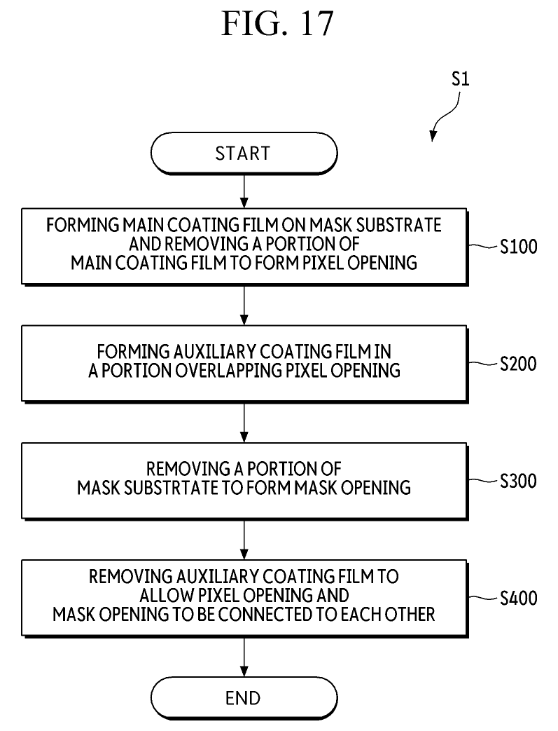

FIG. 17 is a schematic flowchart showing a method of manufacturing a deposition mask according to an embodiment.

Referring to FIG. 17, a method of manufacturing the deposition mask according to an embodiment (S1) may include forming a main coating film on a mask substrate and removing a portion of the main coating film to form a pixel opening (S100), forming an auxiliary coating film in a portion overlapping the pixel opening (S200), removing a portion of the mask substrate to form a mask opening (S300), and removing the auxiliary coating film to allow the pixel opening and the mask opening to be in communication with (or connected to) each other (S400).

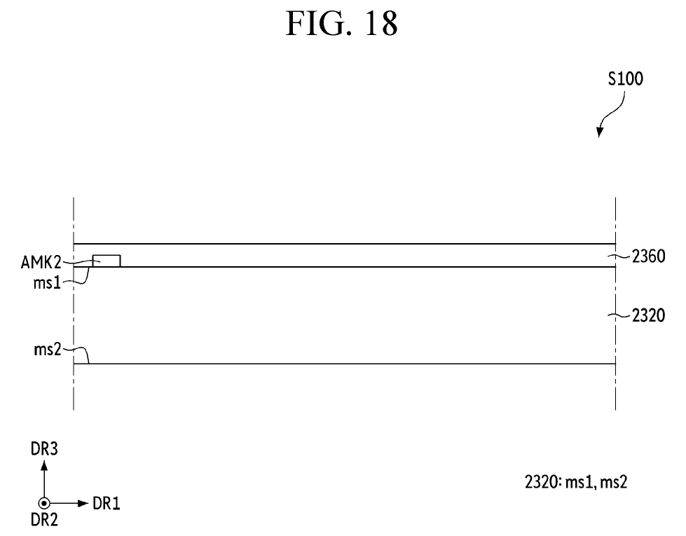

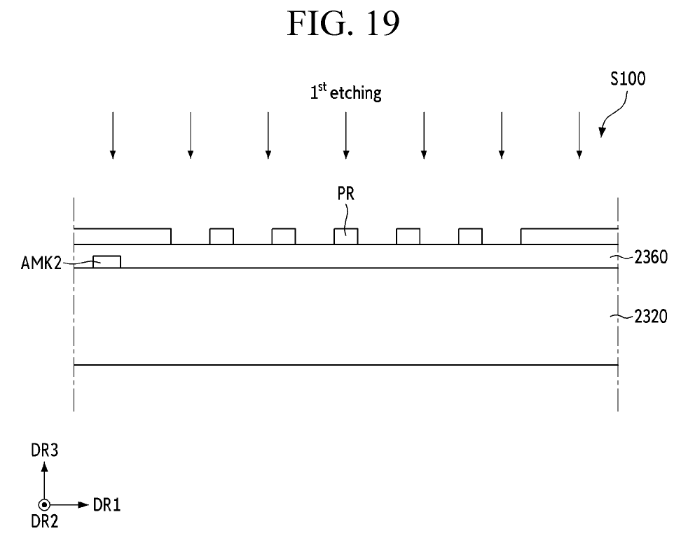

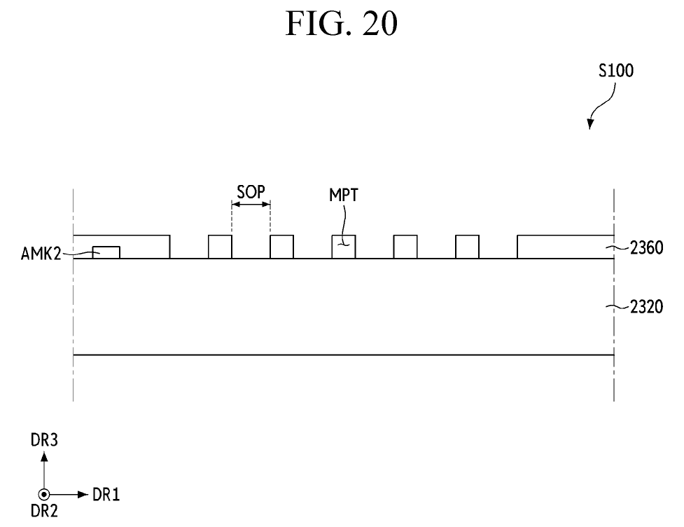

FIGS. 18 to 20 are schematic cross-sectional views showing step (S100) of FIG. 17.

First, the forming of the main coating film on the mask substrate and removing a portion of the main coating film to form the pixel opening (S100) is described.

Referring to FIGS. 18 to 20, a second alignment mark AMK2 and a main coating film 2360 may be formed on a mask substrate 2320. A description of overlapping contents of the mask substrate 2320 and the second alignment mark AMK2 is omitted.

In the process, the main coating film 2360 may be disposed to contact a first surface ms1 of the mask substrate 2320. Although not illustrated in the drawing, the main coating film 2360 may be formed to cover a second surface ms2 and an edge surface (not illustrated) of the mask substrate 2320 according to the process. The main coating film 2360 may be formed at a thickness of about 0.5 μm to about 3 μm on the mask substrate 2320.

In the process, the main coating film 2360 may include silicon nitride (SiNₓ), and be formed through a low pressure chemical vapor deposition (LPCVD) process. For example, the main coating film 2360 may be formed by supplying a first source gas including silicon and a second source gas including nitrogen into a chamber and then reacting the first source gas and the second source gas with each other. For example, a dichlorosilane (DCS) (SiH₂Cl₂) gas may be used as the first source gas, and an ammonia (NH₃) gas may be used as the second source gas.

Subsequently, multiple photoresists PR may be formed on the main coating film 2360. In the process, multiple photoresists PR may be disposed to be spaced apart from each other.

Thereafter, a first etching process (1^{st} etching) is performed using multiple photoresists PR as a mask. For example, a dry-etching process may be performed as the first etching process (1^{st} etching), and for example, a reactive ion etching (RIE) process using a reaction gas such as CHF₃, CH₃F, CH₂F₂, CHF₆, CF₄, C₂F₆, or C₃F₆, and a sputtering gas such as Ar or O₂/Ar may be performed. For example, an inductively coupled plasma (ICP) source or a capacitively coupled plasma (CCP) source may be used as a plasma source.

In the process, portions of the main coating film 2360 may be removed by a certain width by appropriately controlling flow rates of the reaction gas and the sputtering gas, an internal temperature of a process chamber, radio frequency (RF) power for forming plasma, bias power applied to a chuck on which the mask substrate 2320 is put, and the like.

In the process, the main coating film 2360 that does not overlap multiple photoresists PR may be removed, and for this reason, a pixel opening SOP and a mask pattern MPT may be formed. In the process, the mask substrate 2320 may be exposed at a portion that overlaps the pixel opening SOP. In another embodiment, the mask pattern MPT may be integral with the main coating film 2360 and then be separated from the main coating film 2360 with the pixel opening SOP interposed therebetween by the etching process described above.

In the process, multiple photoresists PR may be removed through a stripping and/or ashing process.

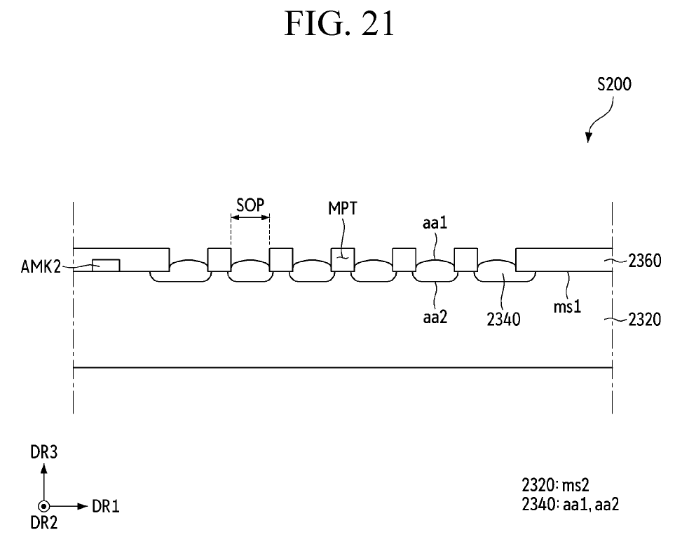

FIG. 21 is a schematic cross-sectional view showing step (S200) of FIG. 17.

Second, the forming of the auxiliary coating film in a portion overlapping the pixel opening (S200) is described.

Referring to FIG. 21, an auxiliary coating film 2340 is formed on the mask substrate 2320 that overlaps the pixel opening SOP. The auxiliary coating film 2340 may be in contact with the main coating film 2360 and a mask pattern MPT.

In the process, the auxiliary coating film 2340 may be formed through a wet thermal oxidation (WTO) process. The WTO process refers to a process of forming an oxide film by oxidizing the interface of the mask substrate 2320 at a high temperature in an atmosphere including water vapor. The process may form a high-quality oxide film, and in this process, silicon is consumed, such that an oxide film may be formed in a ratio of about 55% on the interface of the mask substrate 2320 and in a ratio of about 45% beneath the interface of the mask substrate 2320.

In some embodiments, the auxiliary coating film 2340 may include a first surface aa1 disposed on a side of the third direction DR3 and a second surface aa2 disposed on another side of the third direction DR3 with respect to the first surface ms1 of the mask substrate 2320. The first surface aa1 and the second surface aa2 may be disposed to face each other. For example, with respect to a line extended from the first surface ms1 of the mask substrate 2320, the distance of the first surface aa1 and the distance of the second surface aa2 may be formed to have a ratio of about 11:9.

The auxiliary coating film 2340 may include silicon oxide (SiOₓ) having compressive stress properties. As described above, the main coating film 2360 and the mask pattern MPT may include silicon nitride (SiNₓ) having tensile stress properties, and since the main coating film 2360 and the auxiliary coating film 2340 are formed to contain opposing stresses during the manufacturing process, the deposition mask 2000 may maintain thin-film stress in a neutral state.

The deposition mask 2000 may form the auxiliary coating film 2340 to be in plural numbers in a portion overlapping the pixel opening SOP, and the auxiliary coating film 2340 formed in plural numbers may be spaced apart from each other. The auxiliary coating film 2340 may be formed to be in contact with the mask pattern MPT and the main coating film 2360, thereby maintaining the thin-film stress to be neutral.

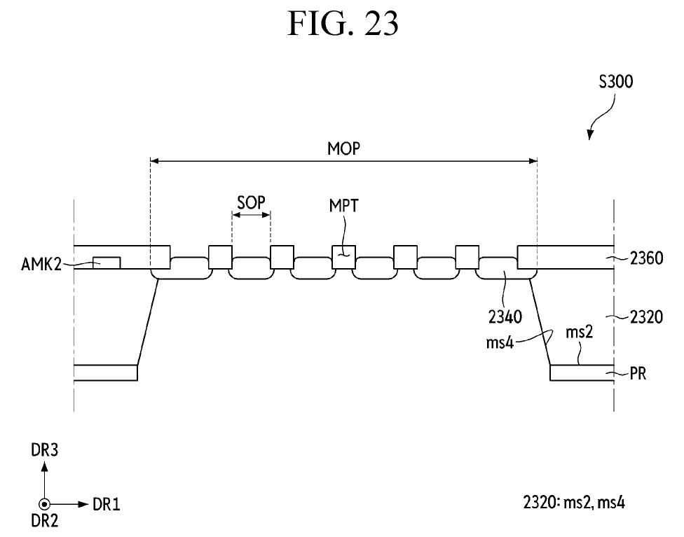

FIGS. 22 and 23 are schematic cross-sectional views showing step (S300) of FIG. 17.

Third, the removing a portion of the mask substrate and forming the mask opening (S300) is described.

Referring to FIGS. 22 and 23, a photoresist PR is formed on a second surface ms2 of the mask substrate 2320 and a second etching process (2^{nd} etching) is performed. Multiple photoresists PR may be formed to overlap the main coating film 2360 and may not overlap the mask pattern MPT.

In the process, the second etching process (2^{nd} etching) may be performed toward the second surface ms2 of the mask substrate 2320. For example, the second etching process (2^{nd} etching) may be performed in the rear direction of the mask substrate 2320. For example, the second etching process (2^{nd} etching) may be performed by a wet-etching process or a dry-etching process.

For example, in case that a wet-etching process is performed as the second etching process (2^{nd} etching), the wet-etching process may be performed using an etchant including tetramethyl ammonium hydroxide (TMAH) or potassium hydroxide (KOH). For example, a <100> crystal direction of the single-crystal silicon substrate used as the mask substrate 2320 may be the third direction DR3, and accordingly, a second side surface ms4 of the mask substrate 2320 may have an inclined surface.

For example, in case that a dry-etching process is performed as the second etching process (2^{nd} etching), the dry-etching process may be performed as a reactive ion etching (RIE) process using a reaction gas such as CHF₃, CH₃F, CH₂F₂, CHF₆, CF₄, C₂F₆, or C₃F₆, and a sputtering gas such as Ar or O₂/Ar, and accordingly, the second side surface ms4 of the mask substrate 2320 may form a right-angle with the second surface ms2 thereof.

In the process, the mask substrate 2320 not overlapping the photoresist PR may be completely removed, and due to this, a mask opening MOP may be formed.

In the process, the mask pattern MPT and the auxiliary coating film 2340 may be disposed to be in contact with each other and the main coating film 2360 and the auxiliary coating film 2340 may be disposed to be in contact with each other, and a thin-film stress may be in a neutral state between the mask pattern MPT and the auxiliary coating film 2340 and between the main coating film 2360 and the auxiliary coating film 2340.

For example, in case that the auxiliary coating film 2340 is not formed to be plural and spaced apart from each other and formed on the entire surface between the mask substrate 2320 and the main coating film 2360, the thin-film stress balance may be broken as the mask substrate 2320 is removed. For example, in case that the auxiliary coating film 2340 is not formed to be plural and spaced apart from each other and formed on the entire surface between the mask substrate 2320 and the main coating film 2360, the auxiliary coating film 2340 has compressive stress properties on the entire surface, and the main coating film 2360 is divided into multiple mask patterns MPT and the main coating film 2360 so that the tensile stress properties may be lower (or relatively lower) than the absolute value of the auxiliary coating film 2340. Accordingly, reliability issues such as cell bursting defect may be caused by the deposition mask. The cell bursting defect described above may occur as the main coating film 2360 is peeled from the mask substrate 2320 or as the main coating film 2360 itself is peeled.

Accordingly, in the deposition mask 2000, the auxiliary coating films 2340 may be formed to be spaced apart with the mask pattern MPT therebetween, thereby solving reliability issues such as cell bursting that can occur during the manufacturing process.

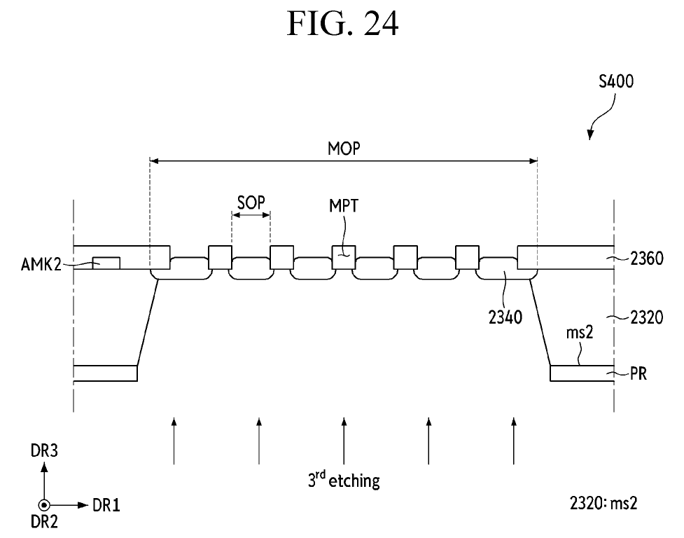

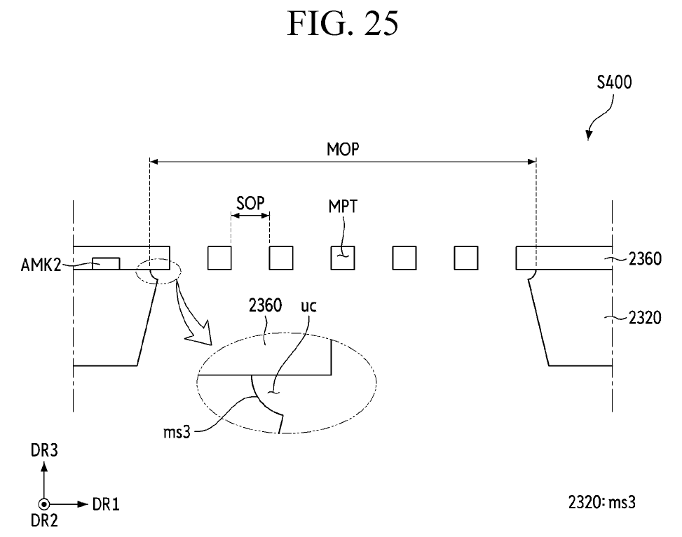

FIGS. 24 and 25 are schematic cross-sectional views showing step (S400) of FIG. 17.

Fourth, the removing the auxiliary coating film to allow the pixel opening and the mask opening to be in connection with each other (S400) is described.

Referring to FIGS. 24 and 25, a third etching process (3^{rd} etching) may be performed following the removing a portion of the mask substrate and forming the mask opening (S300).

In the process, the third etching process (3^{rd} etching) may be performed toward a second surface ms2 of the mask substrate 2320. For example, the third etching process (3^{rd} etching) may be performed in the rear direction of the mask substrate 2320. In the process, the auxiliary coating film 2340 not overlapping the photoresist PR may be completely removed, and due to this, the mask opening MOP and the pixel opening SOP may be in connection with each other.

For example, a wet-etching process may be performed as the third etching process (3^{rd} etching). For example, the wet-etching process may be performed using a buffered oxide etchant (BOE) or an etchant including diluted HF.

In the process, the mask substrate 2320 may have a first side surface ms3, and an undercut uc may be formed between the main coating film 2360 and the first side surface ms3. The first side surface ms3 may be formed as a portion of the mask substrate 2320 is oxidized. A description of overlapping contents in respect to the undercut us is omitted.

Consequently, the deposition mask 2000 illustrated in FIG. 15 may be manufactured.

Referring to FIGS. 17 to 25, in the deposition mask 2000, the auxiliary coating film 2340 may not be formed on the entire surface, and the auxiliary coating film 2340 may be formed only in a portion overlapping the pixel opening SOP after the mask pattern MPT is formed, thereby solving reliability issue such as cell bursting that can occur during the manufacturing process.

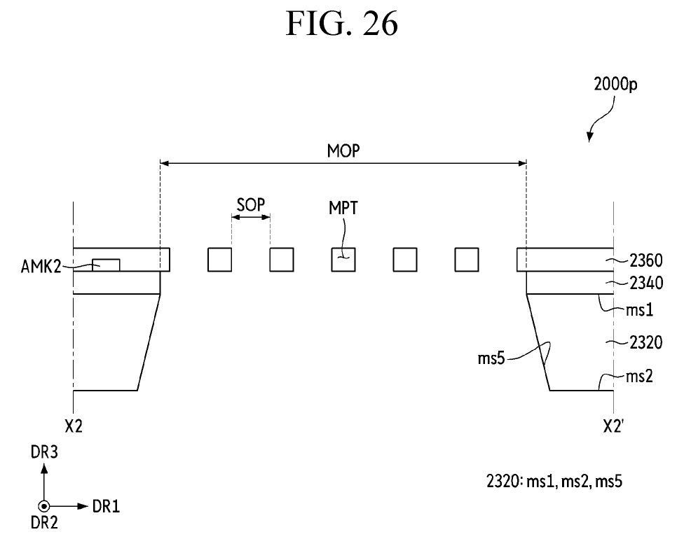

FIG. 26 is a schematic cross-sectional view of another embodiment taken along line X2-X2’ of FIG. 13.

Referring to FIG. 26, a deposition mask 2000p may include a pixel opening SOP and a mask pattern MPT in a portion overlapping a mask opening MOP, and may include a mask substrate 2320, an auxiliary coating film 2340, a second alignment mark AMK2 and a main coating film 2360 sequentially stacked at a portion not overlapping the mask opening MOP.

Hereinafter, the same components as those of the above-described embodiment of the deposition mask 2000 will be denoted by the same reference numerals, and an overlapping description therefor will be omitted or simplified and contents different from those described above will be mainly described.

The mask substrate 2320 included in the deposition mask 2000p may include a first surface ms1, a second surface ms2, and a side surface ms5. The side surface ms5 may be one surface facing the mask opening MOP and connect the first surface ms1 and the second surface ms2.

The auxiliary coating film 2340 may be disposed on the first surface ms1 of the mask substrate 2320. The auxiliary coating film 2340 may be disposed to surround the mask opening MOP.

The auxiliary coating film 2340 may include silicon oxide (SiOₓ) having compressive stress properties.

In some embodiments, the auxiliary coating film 2340 may be disposed even on the second surface ms2 of the mask substrate 2320, but the disclosure is not limited thereto.

The second alignment mark AMK2 may be disposed on the auxiliary coating film 2340. However, the disclosure is not limited thereto, and the location of the second alignment mark AMK2 may vary.

The main coating film 2360 may be disposed on the second alignment mark AMK2 and the auxiliary coating film 2340. The main coating film 2360 may be disposed to surround the mask opening MOP.

The main coating film 2360 may be an inorganic film including inorganic material, and for example, may contain silicon nitride (SiNₓ) having tensile stress properties.

In some embodiments, the main coating film 2360 may include a portion protruding toward the mask opening MOP from the side surface ms5 of the mask substrate 2320, but the disclosure is not limited thereto.

In some embodiments, the main coating film 2360 may be disposed on the second surface ms2 of the mask substrate, but the disclosure is not limited thereto.

The deposition mask 2000p according to an embodiment may include multiple mask patterns MPT in a portion that overlaps the mask opening MOP. Multiple mask patterns MPT may not overlap the mask substrate 2320 in the third direction DR3. A description of overlapping contents of the mask pattern MPT is omitted.

The pixel opening SOP according to an embodiment may be in connection with the mask opening MOP. Accordingly, the mask opening MOP and the pixel opening SOP may provide a passage through which a deposition material for forming the pixel PX of the display panel 100 included in the display device 10 may move.

Hereinafter, a method of manufacturing the deposition mask 2000p will be described.

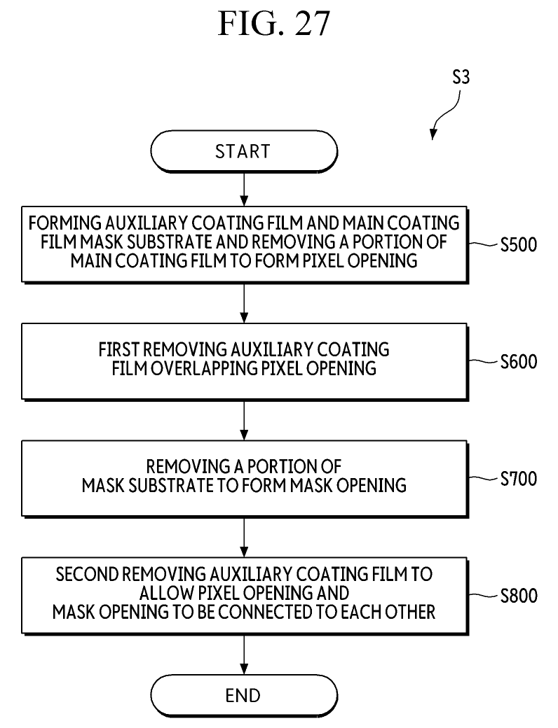

FIG. 27 is a schematic flowchart showing a method of manufacturing a deposition mask illustrated in FIG. 26.

Referring to FIG. 27, a method of manufacturing the deposition mask 2000p according to an embodiment (S3) explains forming an auxiliary coating film and a main coating film on a mask substrate and removing a portion of the main coating film to form a pixel opening (S500), first removing the auxiliary coating film that overlaps the pixel opening (S600), removing a portion of the mask substrate to form a mask opening (S700), and second removing the auxiliary coating film to allow the pixel opening and the mask opening to be connected to each other (S800).

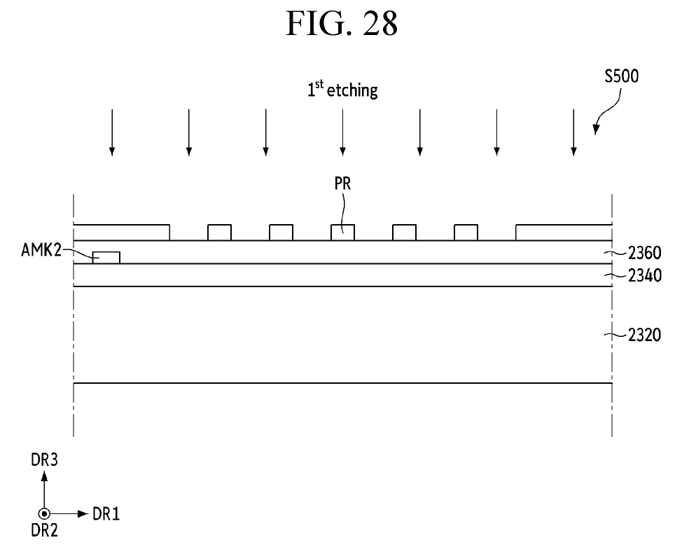

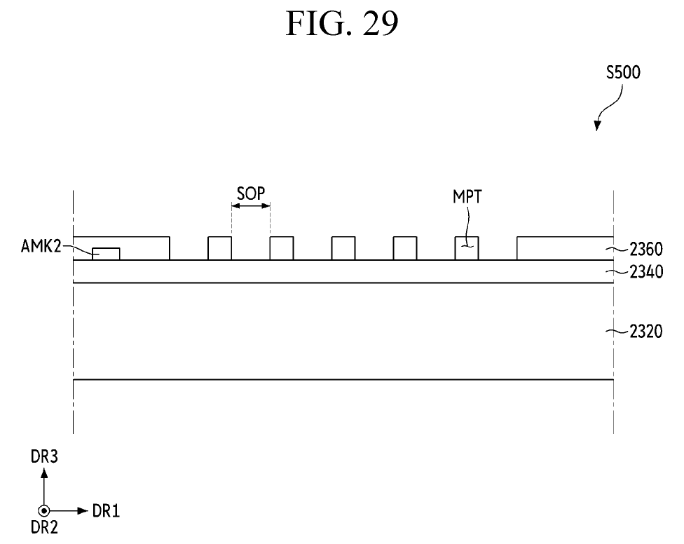

FIGS. 28 and 29 are schematic cross-sectional views of step (S500) of FIG. 27.

First, the forming the auxiliary coating film and the main coating film on the substrate and removing a portion of the main coating film to form the pixel opening (S500) is described.

Referring to FIGS. 28 and 29, an auxiliary coating film 2340 may be formed on the entire surface of a mask substrate 2320, and a second alignment mark AMK2 and a main coating film 2360 may be formed on the auxiliary coating film 2340. The main coating film 2360 may be formed to cover the entire surface of the auxiliary coating film 2340. The description of the mask substrate 2320 and the second alignment mark AMK2 is omitted.

In the process, the auxiliary coating film 2340 may be formed through wet thermal oxidation process (WTO) and may be formed at a thickness of about 0.5 μm to about 3 μm on the mask substrate 2320.

Furthermore, the main coating film 2360 may be formed through a low pressure chemical vapor deposition (LPCVD) process, and may be formed at a thickness of about 0.5 μm to about 3 μm on the mask substrate 2320.

As described above, the auxiliary coating film 2340 may include silicon oxide (SiOₓ) having compressive stress properties, and the main coating film 2360 may include silicon nitride (SiNₓ) having tensile stress properties. Accordingly, a thin-film stress may maintain in a neutral state between the main coating film 2360 and the auxiliary coating film 2340.

Subsequently, multiple photoresists PR may be formed on the main coating film 2360. In the process, multiple photoresists PR may be disposed to be spaced apart from each other. Thereafter, a first etching process (1^{st} etching) is performed using multiple photoresists PR as a mask. For example, a dry-etching process may be performed as the first etching process (1^{st} etching). A description of overlapping content is omitted.

In the process, the main coating film 2360 that does not overlap multiple photoresists PR may be removed, and for this reason, a pixel opening SOP and a mask pattern MPT may be formed. In the process, the auxiliary coating film 2340 may be exposed at a portion that overlaps the pixel opening SOP. In another embodiment, the mask pattern MPT may be integral with the main coating film 2360 and then be separated from the main coating film 2360 with the pixel opening SOP interposed therebetween by the etching process described above.

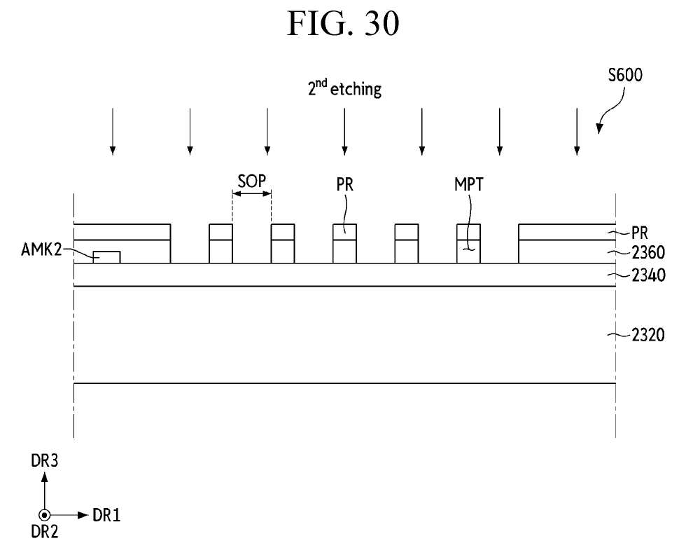

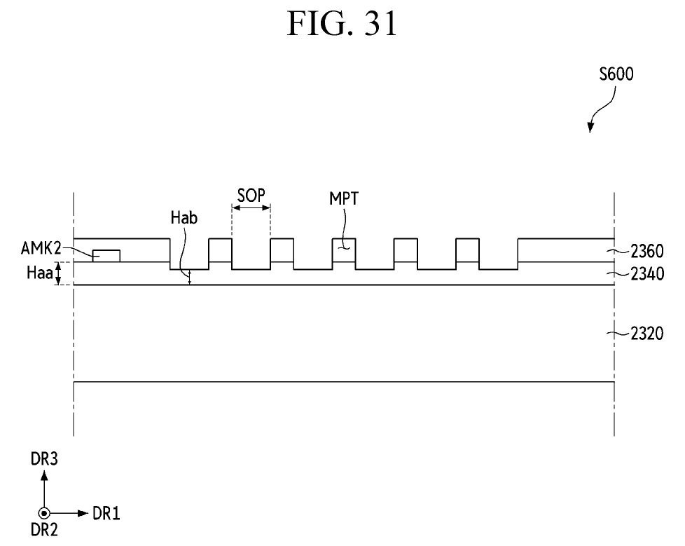

FIGS. 30 and 31 are schematic cross-sectional views of step (S600) of FIG. 27.

Second, the first removing the auxiliary coating film that overlaps the pixel opening (S600) is described.

Referring to FIGS. 30 and 31, a photoresist PR is formed at the same location as multiple photoresists PR used in the first etching process (1^{st} etching), and the auxiliary coating film 2340 is first removed through a second etching process (2^{nd} etching).

In the process, a wet-etching process may be performed as the second etching process (2^{nd} etching), and the wet-etching process may be performed using a buffered oxide etchant (BOE) or an etchant including diluted HF.

In the process, a portion of the auxiliary coating film 2340 that does not overlap multiple photoresists PR may be removed. For example, in the process, a height Hab of the auxiliary coating film 2340 that overlaps the pixel opening SOP may have a height of about half of a height Haa of the original auxiliary coating film 2340.

In the process, multiple photoresists PR may be removed through a stripping and/or ashing process.

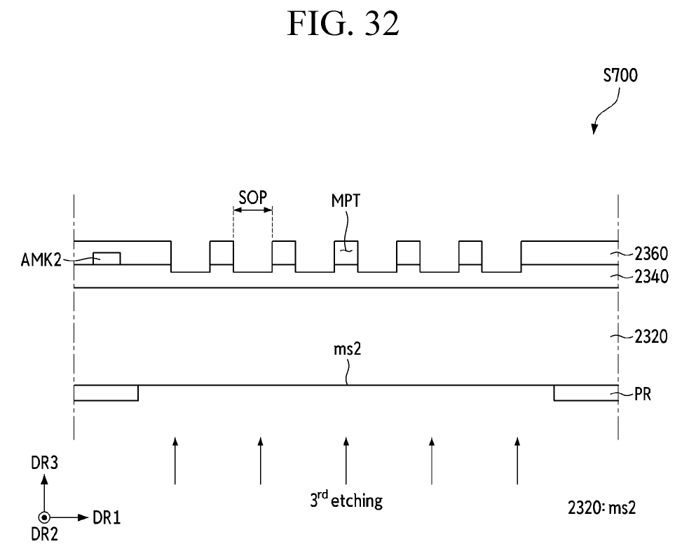

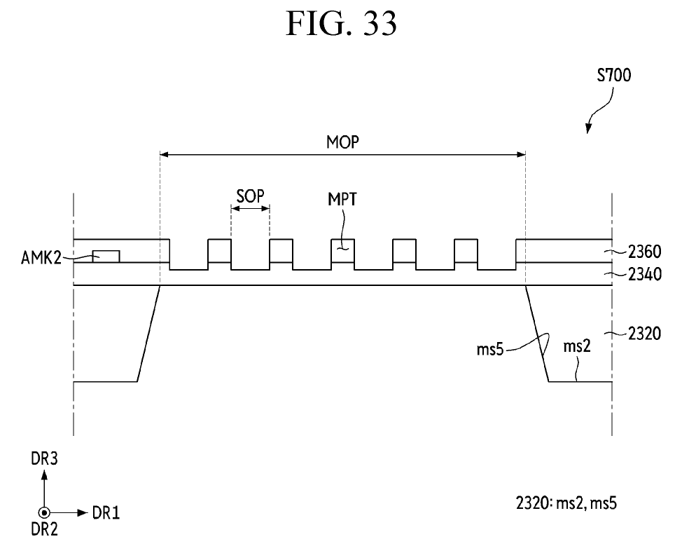

FIGS. 32 and 33 are schematic cross-sectional views of step (S700) of FIG. 27.

Third, the removing a portion of the mask substrate to form the mask opening (S700) is described.

Referring to FIGS. 32 and 33, a photoresist PR is formed on a second surface ms2 of the mask substrate 2320 and a third etching process (3^{rd} etching) is performed. Multiple photoresists PR may be formed to overlap the main coating film 2360 and may not overlap the mask pattern MPT.

In the process, the third etching process (3^{rd} etching) may be performed toward a second surface msa2 of the mask substrate 2320. For example, the third etching process (3^{rd} etching) may be performed in the rear direction of the mask substrate 2320. In the process, the mask substrate 2320 not overlapping the photoresist PR may be completely removed, and due to this, a mask opening MOP may be formed.

For example, the third etching process (3^{rd} etching) may be performed by a wet-etching process or a dry-etching process. For example, in case that a wet-etching process is performed as the third etching process (3^{rd} etching), a side surface ms5 of the mask substrate 2320 may have an inclined surface, and in case that a dry-etching process is performed as the third etching process (3^{rd} etching), the side surface ms5 of the mask substrate 2320 may form a right-angle with the second surface ms2 thereof. A description of overlapping content is omitted.

In the process, the auxiliary coating film 2340 may remain in a portion overlapping the mask opening MOP.

In the process, the mask pattern MPT and the auxiliary coating film 2340 and the main coating film 2360 and the auxiliary coating film 2340 may be disposed to be in contact with each other, and a thin-film stress may be in a neutral state between the mask pattern MPT and the auxiliary coating film 2340 and between the main coating film 2360 and the auxiliary coating film 2340. The mask pattern MPT and the main coating film 2360 may be connected by the auxiliary coating film 2340.

In the deposition mask 2000p, the auxiliary coating film 2340 may be first removed from a portion overlapping the pixel opening SOP so that the auxiliary coating film 2340 is formed to have partially lower thickness, thereby solving reliability issue such as cell bursting that can occur during the manufacturing process. A description of overlapping contents is omitted.

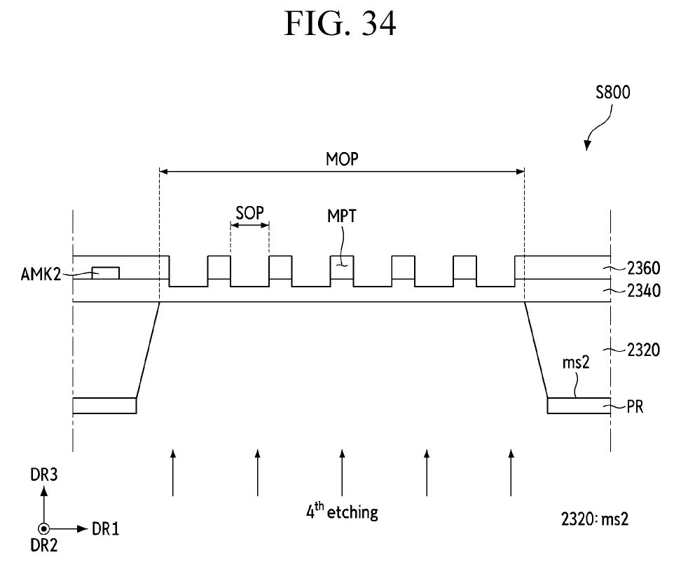

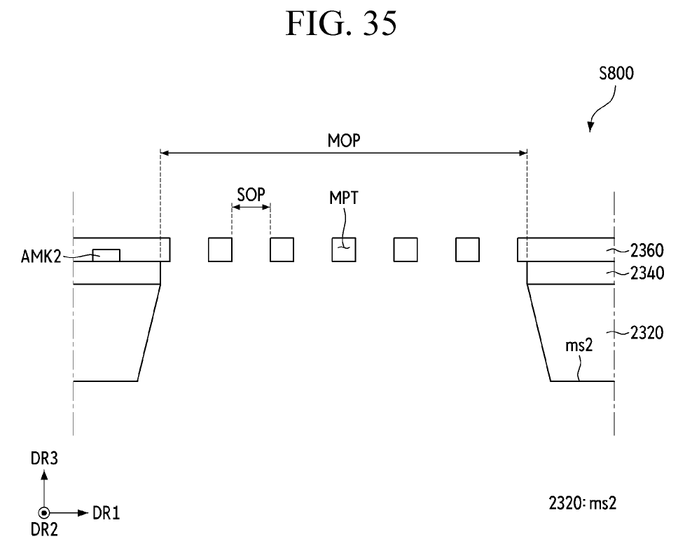

FIGS. 34 and 35 are schematic cross-sectional views of step (S800) of FIG. 27.

Fourth, the second removing the auxiliary coating film to allow the pixel opening and the mask opening to be connected to each other (S800) is described.

Referring to FIGS. 34 and 35, a photoresist PR may be formed on the second surface ms2 of the mask substrate 2320 and a fourth etching process (4^{th} etching) may be performed. Multiple photoresists PR may be formed to overlap the main coating film 2360, and not overlap the mask pattern MPT. For example, a wet-etching process may be performed as the fourth etching process (4^{th} etching). For example, the wet-etching process may be performed using a buffered oxide etchant (BOE) or an etchant including diluted HF.

In the process, the fourth etching process (4^{th} etching) may be performed in a direction of the second surface ms2 of the mask substrate 2320. For example, the fourth etching process (4^{th} etching) may be performed in the rear direction of the mask substrate 2320. In the process, the auxiliary coating film 2340 that does not overlap the photoresist PR may be completely removed, and due to this, the mask opening MOP and the pixel opening SOP may be in connection with each other.

Consequently, the deposition mask 2000p illustrated in FIG. 26 may be manufactured.

Referring to FIGS. 27 to 35, in the deposition mask 2000p, the auxiliary coating film 2340 may be removed separately firstly and secondly to form the height of the auxiliary coating film 2340 in a portion overlapping the pixel opening SOP to be low, thereby solving reliability issue such as cell bursting that can occur during the manufacturing process.

The display device according to an embodiment of the disclosure can be applied to various electronic devices. The electronic device according to an embodiment of the disclosure includes the display device described above, and may further include modules or devices having additional functions in addition to the display device.

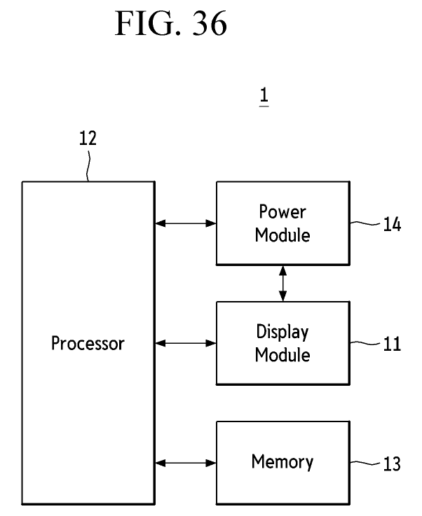

FIG. 36 is a schematic block diagram of an electronic device according to an embodiment of the disclosure.

Referring to FIG. 36, the electronic device 1 according to an embodiment of the disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to an embodiment of the disclosure may be included in the display device 10 according to the embodiments of the disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

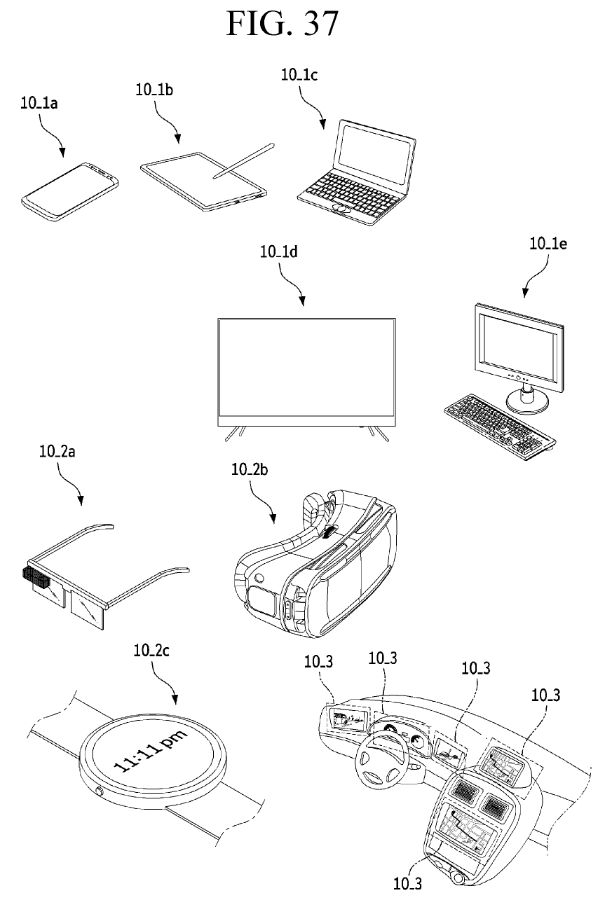

FIG. 37 is a schematic diagram of an electronic device according to various embodiments of the disclosure.

Referring to FIG. 37, various electronic devices to which display devices 10 according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A deposition mask comprising:
a mask substrate including a mask opening;
a main coating film including a mask pattern overlapping the mask opening; and
a pixel opening defined by the mask pattern, the mask pattern spaced apart from each other by the pixel opening,
wherein the mask substrate includes:
a first surface facing the main coating film;
a second surface facing the first surface;
a first side surface connected to the first surface; and
a second side surface connecting the first side surface and the second surface,
the first side surface forms an undercut with the main coating film, and
the mask substrate increases as being closer to the main coating film in a perpendicular direction to the mask substrate.

2. The deposition mask of claim 1,
wherein the first side surface is recessed toward the main coating film in an opposite direction in which the mask opening is disposed.

3. The deposition mask of claim 2,
wherein the main coating film includes a side surface facing the mask opening, and
the side surface of the main coating film is protruding toward the mask opening more than the first side surface of the mask substrate.

4. The deposition mask of claim 3,
wherein the first surface and the second surface are connected by the first side surface and the second side surface.

5. The deposition mask of claim 4,
wherein an inclination angle formed between the second surface and the second side surface includes at least one of an obtuse angle or right-angle.

6. The deposition mask of claim 1,
wherein the main coating film is in contact with the first surface,
the mask substrate includes silicon, and
the mask substrate has a circular shape in a plan view.

7. The deposition mask of claim 1,
wherein the mask pattern and the main coating film are disposed on a same line,
the mask pattern and the main coating film includes a same material, and
the mask pattern and the main coating film include silicon nitride.

8. The deposition mask of claim 1,
wherein, in a portion overlapping the first side surface in a direction parallel to the mask substrate, the mask opening increases as being closer to the main coating film.

9. The deposition mask of claim 1,
wherein the pixel opening and the mask opening are connected to each other.

10. A method of manufacturing a deposition mask, the method comprising:
forming a main coating film on a mask substrate and removing a portion of the main coating film to form a pixel opening;
forming an auxiliary coating film on the mask substrate in a portion overlapping the pixel opening;
removing a portion of the mask substrate to form a mask opening; and
removing the auxiliary coating film to allow the pixel opening and the mask opening to be in connection with each other,
wherein, in the forming of the auxiliary coating film, the auxiliary coating film is formed in plural numbers, and each of the auxiliary coating films is spaced apart from each other.

11. The method of manufacturing a deposition mask of claim 10, further comprising:
forming a mask pattern overlapping the mask opening and defining the pixel
opening,
wherein the auxiliary coating films are spaced apart from each other with respect to the mask pattern.

12. The method of manufacturing a deposition mask of claim 11, wherein, in the forming of the auxiliary coating film, the auxiliary coating film is in contact with the main coating film and the mask pattern.

13. The method of manufacturing a deposition mask of claim 12, wherein the auxiliary coating film includes silicon oxide.

14. The method of manufacturing a deposition mask of claim 10, wherein, in the forming of the auxiliary coating film, the auxiliary coating film is formed by a thermal oxidation (WTO) process.

15. The method of manufacturing a deposition mask of claim 10, wherein, in the removing of the mask substrate and the auxiliary coating film, an etching process removing the mask substrate and the auxiliary coating film is performed in a rear direction of the mask substrate.

16. An electronic device comprising:
a display device formed using a deposition mask, the deposition mask comprising:
a mask substrate including a mask opening;
a main coating film including a mask pattern overlapping the mask opening; and
a pixel opening defined by the mask pattern, the mask pattern spaced apart from each other by the pixel opening, wherein
the mask substrate includes:
a first surface facing the main coating film;
a second surface facing the first surface;
a first side surface connected to the first surface; and
a second side surface connecting the first side surface and the second surface,
the first side surface forms an undercut with the main coating film, and
the mask substrate increases as being closer to the main coating film in a perpendicular direction to the mask substrate.

17. The electronic device of claim 16, wherein the first side surface is recessed toward the main coating film in an opposite direction in which the mask opening is disposed.

18. The electronic device of claim 17, wherein
the main coating film includes a side surface facing the mask opening, and
the side surface of the main coating film protrudes toward the mask opening more than the first side surface of the mask substrate.

19. The electronic device of claim 18, wherein the first surface and the second surface are connected by the first side surface and the second side surface.

20. The electronic device of claim 19, wherein an inclination angle formed between the second surface and the second side surface includes at least one of an obtuse angle or right-angle.
